(19) United States
(12) Patent Application Publication
(10) Pub. No.: US 2015/0129772 A1
(43) Pub. Date: May 14, 2015

(54) SURFACE MICRO-MACHINED MULTI-POLE ELECTROMAGNETS

(71) Applicant: THE REGENTS OF THE UNIVERSITY OF CALIFORNIA, Oakland, CA (US)

(72) Inventors: Robert N. Candler, La Canada Flintridge, CA (US); Jere Harrison, Los Angeles, CA (US); Oscar M. Stafsudd, Los Angeles, CA (US); Pietro Musumeci, Los Angeles, CA (US); Abhijeet Joshi, Los Angeles, CA (US)

(21) Appl. No.: 14/517,420

(22) Filed: Oct. 17, 2014

Related U.S. Application Data
(60) Provisional application No. 61/892,976, filed on Oct. 18, 2013.
(60) Provisional application No. 61/892,968, filed on Oct. 18, 2013.

(51) Int. Cl. H01J 37/141

(52) U.S. Cl. CPC H01J 37/141; H01J 2237/1415
USPC 250/396 ML

(57) ABSTRACT

A structure includes multiple electromagnets with sub-100 micrometer feature size. Each electromagnet includes a substrate defining multiple filled trenches with conductive fillers, a first isolation layer disposed over the conductive fillers such that a portion of each conductive filler is exposed by the first isolation layer, a core disposed over the first isolation layer, and a second isolation layer covering the core. The second isolation layer has a top surface, and winding interconnects extend from a plane defined by the top surface of the second isolation layer to the conductive fillers such that each winding interconnect contacts one of the conductive fillers on a portion exposed by the first isolation layer. A conductive layer includes upper connectors to electrically connect winding interconnects positioned on opposite sides of the core. The trenches, winding interconnects, and upper connectors are electrically connected to form windings around the core.

### CROSS-REFERENCE TO RELATED PATENT APPLICATIONS

This application claims the benefit of U.S. Provisional Patent Applications 61/892,968 filed Oct. 18, 2013 to Candler et al., titled “Surface Micro-Machined Multi-Pole Electromagnets,” and 61/892,976 filed Oct. 18, 2013 to Candler et al., titled “Stacked Micro-Machined Multi-Pole Electromagnet,” the contents of which are incorporated herein by reference in their entirety.

### STATEMENT REGARDING FEDERALLY SPONSORED RESEARCH OR DEVELOPMENT

This invention was made with Government support under N66001-11-1-4197 and N66001-12-1-4209, awarded by the Defense Advanced Research Projects Agency (DARPA) by way of the U.S. Navy, Space and Naval Warfare Systems Command. The Government has certain rights in the invention.

### BACKGROUND

A technological gap exists between the nanometer (nm) to millimeter (mm) scale of beams in charged particle beam manipulation systems and the millimeter (mm) to meter (m) scale of permanent magnet and electromagnet optical components. It would be beneficial to have available micrometer (μm) or smaller scale optical components for use in beam manipulation systems such as, for example, laser undulators, inverse Compton scattering sources, laser Wakefield accelerators, dielectric accelerators, and electron or proton microscopes.

Current systems that use beam manipulation tend to be very large, very heavy, and very expensive, limiting their use. Further, the beam manipulation components in these systems are generally hand-manufactured and hand-adjusted for a specific use, and are not readily adaptable for other uses.

Charged particle beam optical elements such as dipoles, quadrupoles and higher order multi-poles play a role in applications of high quality electron beams throughout science and medicine, from microscopy and diffraction to cancer radiotherapy and the production of intense and coherent X-Rays. For these demanding applications, it is important to improve the performance and reduce the size of beam transport systems. For example: matching the particle beam width to the optimal size in free electron laser and inverse Compton scattering light sources (ICS) would dramatically improve power efficiency and source brightness, but ultra-high gradient focusing and short effective magnetic length are required in order to achieve sub-mm spot sizes; in electron microscopes, stronger magnetic lenses could be used to reduce the beam size at the sample and/or increase the magnification of the system while higher order magnetic elements would be needed to correct the effect of aberrations on the instrument spatial resolution; in advanced plasma Wakefield accelerator applications, matching the beam to the extreme strong focusing of a plasma channel necessitates very small spots at injection using very strong very short focal length quadrupoles, and the large angular divergence leaving the laser plasma Wakefield accelerator necessitates high-gradient focusing over a short distance to minimize bunch elongation and retain high peak current; in multi-stage laser dielectric accelerators and undulator structures, strong magnetic optics matched in size-scale to the sub-mm accelerator gap are needed to realize a full scale demonstration of a light-source system; and in relativistic electron microscopes, strong focusing and aberration correction optics are needed to reduce the effects of space-charge and chromatic aberrations on the imaging beam and to reduce the instrument size.

It would thus be beneficial for the above systems, and others, to have available beam manipulation components that are manufactured using automated small-feature-scale manufacturing processes to reduce size, weight and cost of the overall system. It would be further beneficial to have the capability to control the system for rapid adaptation to different uses or conditions.

### SUMMARY

In one aspect, a structure includes multiple electromagnets with sub-100 micrometer feature size. Each electromagnet includes a substrate defining multiple trenches filled with conductive fillers, a first isolation layer disposed over the conductive fillers such that a portion of each conductive filler is exposed by the first isolation layer, a core disposed over the first isolation layer, and a second isolation layer covering the core. The second isolation layer has a top surface, and winding interconnects extend from a plane defined by the top surface of the second isolation layer to the conductive fillers such that each winding interconnect contacts one of the conductive fillers on a portion exposed by the first isolation layer. A conductive layer includes upper connectors to electrically connect winding interconnects positioned on opposite sides of the core. The trenches, winding interconnects, and upper connectors are electrically connected to form windings around the core. A third isolation layer may be disposed conformally over the substrate and trenches so that a portion of the trenches are electrically isolated from the substrate. The conductive fillers may fill the trenches to the surface of the substrate.

The electromagnets may be formed as an n-tupole, where n is any integer. The n-tupole magnets may be connected to form one of a closed shape or a linear shape, and the n-tupole magnets may be symmetric or non-symmetric.

The electromagnets may be formed as multiple electromagnets positioned adjacent to each other. In some embodiments, stacking interconnects extend between the substrates of two adjacent multi-pole electromagnets.

The structure may be configured for implementation in one of a particle beam steering optics device, a particle beam focusing optics device, a particle beam aberration correcting device, a mass spectrometer, a single cell MRI imaging device, a magnetophoresis device, a diamagnetophoresis device, an ion trap, a high energy beam focusing device, a low energy beam focusing device, a device coupling a charged particle beam and a photon beam, and an electron imaging device that directly or indirectly records the presence of electrons in space and time.

In some embodiments, for at least one of the electromagnets, the windings are a plurality of windings individually controlled, thereby configuring the electromagnet for a desired field.

In another aspect, a multi-pole electromagnet structure with sub-100 micrometer feature size includes a substrate defining multiple trenches filled with conductive fillers, a first isolation layer disposed over the conductive fillers such that a portion of each conductive filler is exposed by the first isolation layer, a core disposed over the first isolation layer, and a second isolation layer covering the core. The second isolation layer has a top surface, and winding interconnects extend from a plane defined by the top surface of the second isolation layer to the conductive fillers such that each winding interconnect contacts one of the conductive fillers on a portion exposed by the first isolation layer. A conductive layer includes upper connectors to electrically connect winding interconnects positioned on opposite sides of the core. The trenches, winding interconnects, and upper connectors are electrically connected to form windings around the core. A third isolation layer may be disposed conformally over the substrate and trenches so that a portion of the trenches are electrically isolated from the substrate. The conductive fillers may fill the trenches to the surface of the substrate.

The electromagnet structure may be formed as an undulator, or as an n-tupole, where n is any integer.

In some embodiments, the electromagnet structure includes groups of multi-pole electromagnets configured as quadrupoles alternating with groups of multi-pole electromagnets configured as sextupoles.

In some embodiments, the electromagnet structure includes groups of electromagnets configured as quadrupoles and dipoles simultaneously.

In some embodiments, the electromagnet structure includes groups of electromagnets configured as quadrupoles, dipoles, and octopoles simultaneously.

In some embodiments, the electromagnet structure includes groups of electromagnets configured as sextupoles and dipoles simultaneously.

In some embodiments, the electromagnet structure includes groups of electromagnets configured as sextupoles, dipoles, and dodecapoles simultaneously.

In some embodiments, the electromagnet structure includes groups of electromagnets configured as octopoles, dipoles, quadrupoles, and hexadecapoles, simultaneously.

In some embodiments, the electromagnet structure includes groups of electromagnets configured as decapoles, dipoles, and icosapoles simultaneously.

In another aspect, an electromagnet structure includes multiple multi-pole electromagnets each having multiple windings controlled individually or in groups to selectively configure each of the multi-pole electromagnets. The electromagnet structure may have sub-100 micrometer feature size.

In one embodiment, the electromagnet structure includes a controller, wherein each winding of the multi-pole electromagnets is individually controlled by the controller.

In some embodiments, the electromagnet structure includes groups of multi-pole electromagnets configured as quadrupoles alternating with groups of multi-pole electromagnets configured as dipoles.

In some embodiments, the multi-pole electromagnets are stacked, and electrically connected together.

In some embodiments, the multi-pole electromagnets are stacked, with electrical circuits interposed between.

In various embodiments of various aspects, a field gradient of one of the electromagnets exceeds at least one of 570 Tesla/meter, 700 Tesla/meter, 1,000 Tesla/meter, 1,500 Tesla/meter, 2,000 Tesla/meter, 3,000 Tesla/meter, 4,000 Tesla/meter, 5,000 Tesla/meter, 6,000 Tesla/meter, 8,000 Tesla/meter, 10,000 Tesla/meter, and 20,000 Tesla/meter.

### BRIEF DESCRIPTION OF THE DRAWINGS

FIG. 1 is a conceptual drawing of one implementation of a period of a micro-machined undulator.

FIG. 2 illustrates a top view depiction of a period of an undulator with multiple windings around each finger of a multi-fingered yoke.

FIG. 3 illustrates one quadrupole concept

FIG. 4 is an image of windings in an implementation of the quadrupole concept.

FIG. 5 illustrates four stages of fabrication of an electromagnet in one embodiment.

FIG. 6A illustrates an example of a yoke.

FIG. 6B is a scanning electron micrograph of a multi-fingered yoke fabricated for use in an undulator.

FIG. 6C shows a picture of a multi-fingered yoke positioned over trenches.

FIG. 7 is a picture of a fabricated device after a fabrication stage.

FIG. 8A is a conceptual drawing of the device after a fabrication stage.

FIG. 8B is a picture of fabricated upper connectors after a fabrication stage.

FIG. 9 is a top view picture of multiple batch-fabricated electromagnets.

FIG. 10A is a top view picture of a quadrupole after a fabrication stage.

FIG. 10B is a perspective view of a quadrupole after a fabrication stage.

FIG. 11A illustrates an undulator.

FIG. 11B illustrates a quadropole.

FIG. 12 illustrates a five-stage fabrication technique.

FIG. 13A illustrates a 200 μm gap quadrupole after a fabrication stage.

FIG. 13B illustrates a 400 μm gap quadrupole after another fabrication stage.

FIG. 14 illustrates a setup for magnetic characterization using pulsed wire measurement.

FIG. 15 illustrates results of a simulated optical characterization of a quadrupole.

FIG. 16A illustrates a setup for a low-energy beam test.

FIG. 16B is a block diagram representing a setup for a low-energy beam test.

FIG. 16C shows measured data for a beam centroid steered right, left, down, and up.

FIGS. 16D and 16E show, for one embodiment, field gradient across the X-axis transverse direction (FIG. 16D) and Y-axis transverse direction (FIG. 16E), calculated from magnetic field measurements.

FIG. 16F is a plot of a field gradient.

FIG. 16G is a plot of a measured beam RMS width.

FIG. 17A illustrates a transverse (y-axis) quadropole magnetic field for I=1 A in a 4-pole electromagnet.

FIG. 17B is a plot of quadrupole field gradient (dB_{y}/dx) along the longitudinal axis in the center of the 4-pole electromagnet for I=1 A.

FIG. 18 illustrates a quadrupole with stacking interconnects.

FIG. 19 illustrates an example of seven stages for fabricating a quadrupole.

FIG. 20 is an optical microscope image of a fabricated 200 μm gap quadrupole bottom winding metal after a fabrication stage.

FIG. 21 is a scanning electron micrograph of fabricated 200 μm gap quadrupole vias after a fabrication stage.

FIG. 22 is a scanning electron micrograph of a fabricated 200 μm gap quadrupole structure after another fabrication stage.

FIG. 23 is a scanning electron micrograph of a fabricated 400 μm gap quadrupole electromagnet after a fabrication stage.

FIG. 24 is an optical microscope image of a fabricated 600 μm gap quadrupole electromagnet after packaging and wirebonding to a PCB.

FIG. 25 illustrates stacked quadrupoles.

FIG. 26 illustrates beam spot steering with a single 4-pole electromagnet powered in dipole mode.

FIG. 27 is a calculated electron beam trajectory through a multi-pole electromagnet stack of eight dies.

FIG. 28 illustrates triplet geometry, where quadrupoles are rotated 90° to achieve focusing in both transverse directions.

FIG. 29 illustrates focusing using triplet geometry.

FIG. 30 shows a top-view subsection of a 200 μm gap multi-pole electromagnet powered in quadrupole mode.

FIG. 31A is a simulation of electron beam profile when the quadrupole is off.

FIG. 31B is a simulation of electron beam profile when the quadrupole is on.

FIG. 32 illustrates beam size measurements of focusing an emittance-limited beam.

FIG. 33 shows an analysis of electron beam shape measurement of 1000 shots with quadrupole focusing drive current between −3 A and +3 A.

FIG. 34 illustrates the use of an interposer die between stacked electromagnet dies.

FIGS. 35A and 35B show focusing of the transverse beam envelope for a proton gantry focusing system.

FIG. 36A illustrates dipole fields from 2, 4, and 6-pole Co₅₈Ni₁₃Fe₃₉ core electromagnets at saturation.

FIG. 36B illustrates quadrupole fields from 4-pole CoNiFe core electromagnets at saturation with a superimposed dipole field shifting the quadrupole field centroid left, with the quadrupole field centered, and shifting the quadrupole field centroid right.

FIG. 37 illustrates the use of a non-symmetric 4-pole electromagnet to produce a region of both high field intensity and high field gradient

FIG. 38 illustrates a block diagram including a controller for controlling windings of a multi-pole electromagnet.

### DETAILED DESCRIPTION

Microfabricated electromagnets can produce fields that store orders of magnitude more energy than electrostatic devices, and have clear scaling advantages over macro-scale magnetic counterparts in field gradient strength, frequency response, and integration with circuits. To date, however, the magnetic field interaction length has been too short for microfabricated electromagnets to reach applications where high gradient or fast response is valuable. To push the magnetic field generation limits of miniature devices, thick films are used. However, such films exacerbate inter-film adhesion issues and introduce unique lithography challenges. Additionally, shear stress at interfaces between films with internal stress and dissimilar expansion coefficients scale with film volume.

The microfabrication techniques described in this disclosure may be used for fabrication of multi-pole electromagnets, such as undulators, n-tupole electromagnets (where ‘n’ is an odd or even integer) and other multi-pole configurations. Examples include but are not limited to pentupoles, octopoles, decapoles, and so on. Quadrupoles and undulators are described throughout this document by way of non-limiting examples. The feature size of the multi-pole electromagnets is sub-mm, and further is sub-100 μm, where the term feature size includes but is not limited to gap width and conductor width.

Electromagnet performance scaling indicates that decreasing the gap between poles is a direct way to improve dipole field strength and quadrupole field gradient. For example, magnetic circuit analysis of a small-gap dipole electromagnet with a high-permeability yoke yields B=μ₀nI/2r field amplitude, where μ₀ is the permeability of free space, n is the number of electromagnet turns, I is the electromagnet current, and r is the distance between the center of the gap and pole tip. For charged particle focusing, quadrupoles can be characterized by their effective magnetic length Lₘ and normalized strength k²=qg/p where q is the particle charge, g is the field gradient, and p is the beam momentum. The focal length for a single quadrupole can be written as f¹=k²Lₘ in the thin lens approximation (e.g., when the focal length is greater than the effective magnetic length, f>>Lₘ).

The field gradient in a small-gap quadrupole with a high-permeability yoke can be approximated as g=2μ₀nI/r².

The strength of the electromagnet is related inversely to the distance between the pole tips for both dipole and quadrupole fields while material parameters such as the magnetic saturation of the yoke, or the maximum electromagnet winding current density, are not affected by scaling. Additionally, a smaller electromagnet gap reduces the total magnetic flux necessary to produce a field. This is reflected in the electromagnet design as a reduced number of winding turns, lowering the resistance, inductance, and the circuit time constant.

For pulsed beam sources, a fast magnet response allows short-duty-cycle electromagnet switching enabling pulse-to-pulse reconfiguration of the beam optics, and reduces power consumption. As a result, scaling from traditional cm-scale out-of-vacuum magnetic optics to sub-mm-scale in-vacuum micro-machined optics provides a path for ultra-high-gradient focusing and fast reconfigurable beam control on a size-scale compatible with compact accelerators while reducing the size, weight, and power consumption of beam transport systems.

Reducing the electromagnet gap through micromachining manufacturing techniques places constraints on the beam source and transport system. To pass through the 100 μm-scale good field region of a micro-machined quadrupole electromagnet, the initial electron beam must be smaller than the electromagnet gap or focusable below 100 μm spot-size by an upstream lens. Recently, progress has been made in high brightness electron sources which are now capable of producing high current electron beams with sub-mm-mrad emittances, thus enabling the development of small-aperture magnetic elements. However, due to the short effective magnetic length (sub-mm), the use of these magnets is at this stage most appropriate for low energy beamlines (up to few MeV). To extend application to high energy beams (over 100 MeV), new microfabrication techniques are described to increase the effective magnetic length of the electromagnet to the mm-scale.

Because the magnetic field gradient in a quadrupole lens scales inversely with the gap between the pole tips, a sub-mm gap quadrupole enables multi-kilo Tesla per meter (kTesla/m) gradients and β<10 cm focusing lattices. Surface-micromachining technology used to batch manufacture microelectromechanical system (MEMS) products can achieve μm-to-mm-scale features in a variety of metals, semiconductors, and insulators with sub-μm precision.

Leveraging MEMS fabrication technologies, undulators with 400 μm period length, 50 μm yoke thickness, and 100 μm gap, and quadrupoles with 200 μm gap, 400 μm gap, and 600 μm gap have been fabricated. Impedance measurement of the electromagnets closely matches simulation: 137 milliohm (ma) resistance and 17 nanoHenry (nH) inductance for individual 25 μm gap undulator periods, and 58 mΩ and 30 nH for 600 μm gap quadrupoles. These electrical values indicate a peak undulator field of 0.135 Tesla, quadrupole gradients exceeding 1400 Tesla/m, and an electrical time constant less than 1 μs, enabling rapid low-duty-cycle pulsing. These microfabricated undulators and quadrupoles may be used, for example, as insertion devices and focusing lattices for compact light sources.

Multi-pole electromagnets may have gap sizes, for example, in the range of 1 μm to 1000 μm, 1 μm to 800 μm, 1 μm to 600 μm, 1 μm to 400 μm, 1 μm to 200 μm, 1 μm to 100 μm, 1 μm to 99 μm, 1 μm to 95 μm, 1 μm to 75 μm, 1 μm to 50 μm, and 1 μm to 25 μm, 10 μm to 1000 μm, 10 μm to 800 μm, 10 μm to 600 μm, 10 μm to 400 μm, 10 μm to 200 μm, 10 μm to 100 μm, 100 μm to 1000 μm, 100 μm to 800 μm, 100 μm to 600 μm, 100 μm to 400 μm, and 100 μm to 200 μm. As the gap width decreases, the associated gradient increases. For example, the gradient may exceed 570 Tesla/m, exceed 1000 Tesla/m, exceed 1500 Tesla/m, exceed 2000 Tesla/m, exceed 5000 Tesla/m, or exceed 10000 Tesla/m.

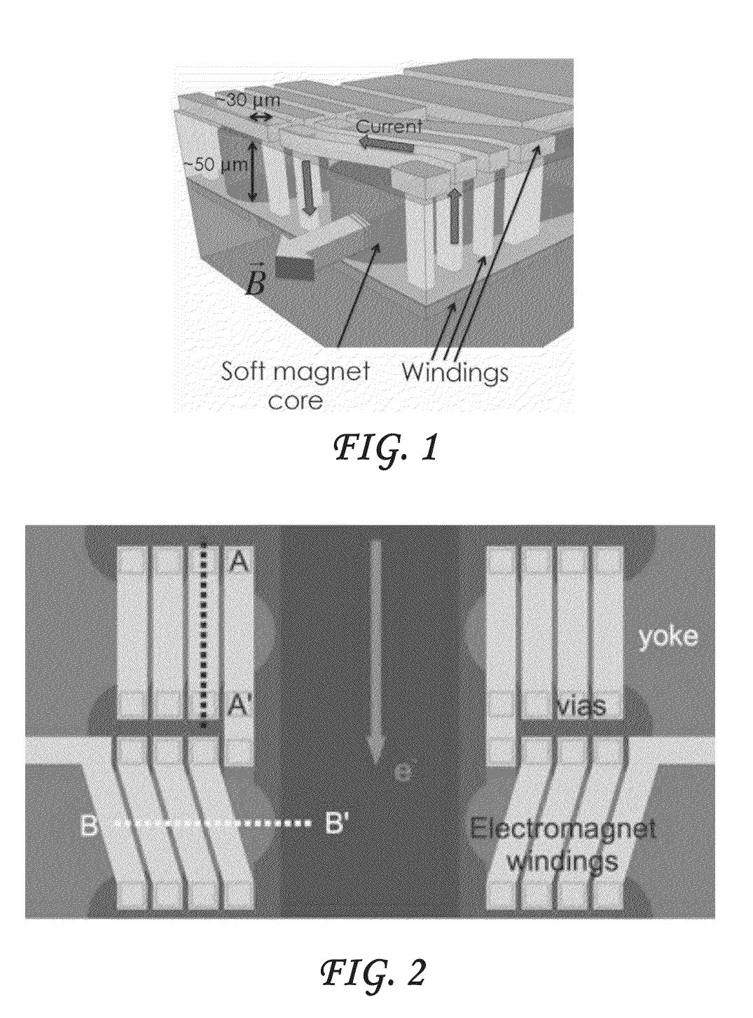

There are many forms in which a multi-pole electromagnet may be manufactured. FIGS. 1-4 are provided by way of illustration for undulators and quadrupoles.

FIG. 1 is a conceptual drawing of one implementation of a single period of a micro-machined undulator. FIG. 2 illustrates a top view depiction of a single period of an undulator with multiple windings around each pole of a multi-pole yoke. The windings are formed of conductive trenches, vias, and connectors, as described below.

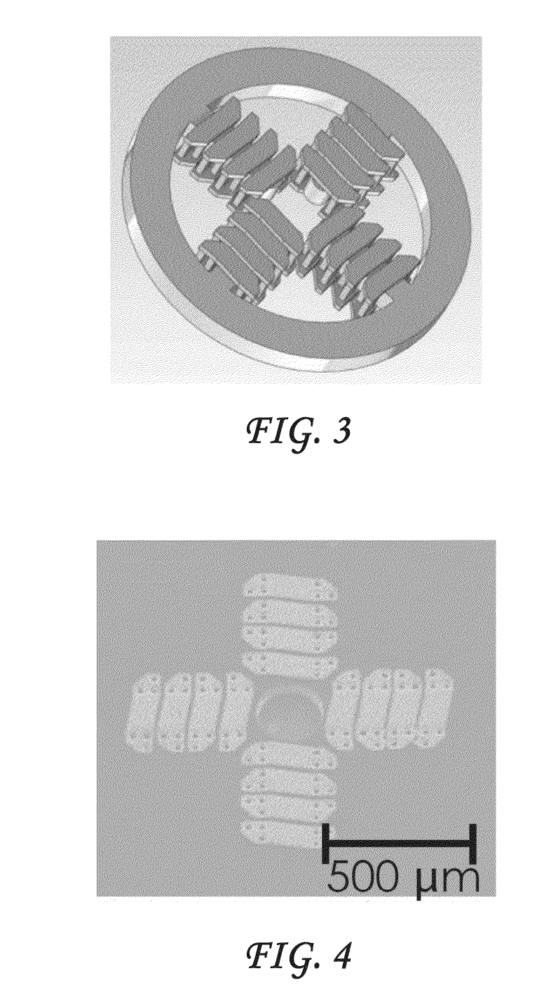

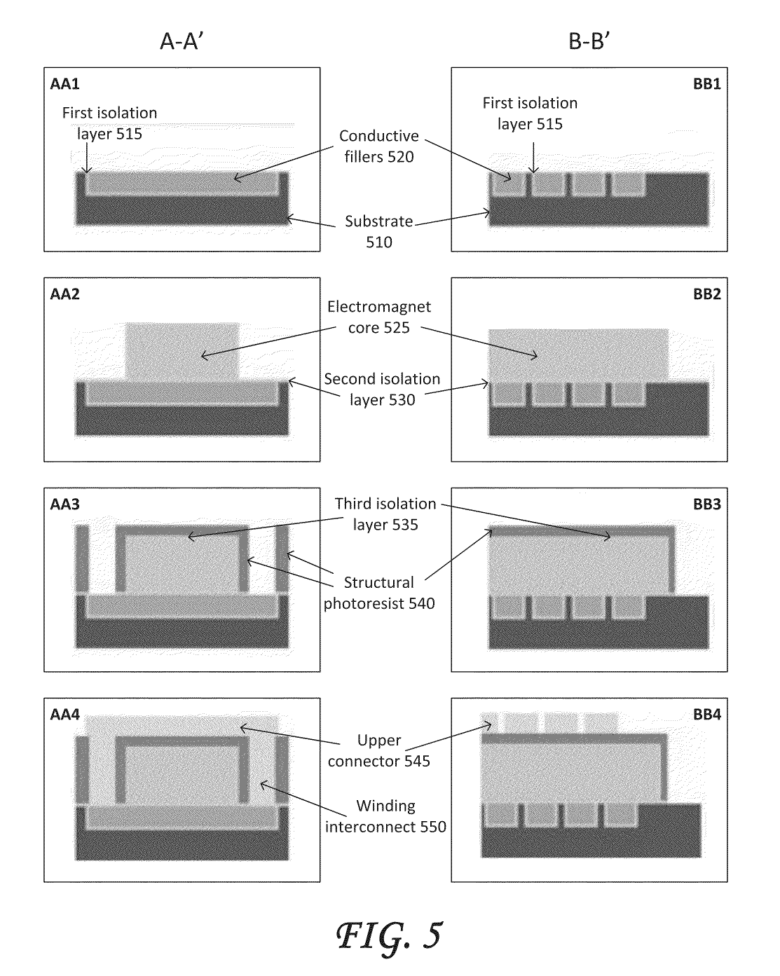

FIG. 3 illustrates one quadrupole concept, and FIG. 4 is an image of windings of an implementation of the quadrupole concept of FIG. 3.

FIG. 5 illustrates a four stage fabrication technique of an electromagnet in one embodiment, and is described with respect to the example of the undulator illustrated in FIG. 2. The A-A′ (left column) and B-B′ (right column) cross sections of FIG. 5 refer to the cross-section indications A-A′ and B-B′, respectively, in FIG. 2.

In the first stage of the fabrication, labeled AA1 and BB1 in FIG. 5, trenches are formed in a substrate 510 and filled with conductive material (e.g., copper) to form conductive fillers 520 for the bottom portion of the windings. In this embodiment, to form the trenches in the substrate, the substrate is etched using deep reactive-ion etching (DRIE), and the trenches are isolated (e.g., first isolation layer 515) with a thermal oxidation. The trenches are then sputter plated with seed and filled by electroplating. The conductive fillers 520 are then smoothed with a chemical mechanical planarization (CMP).

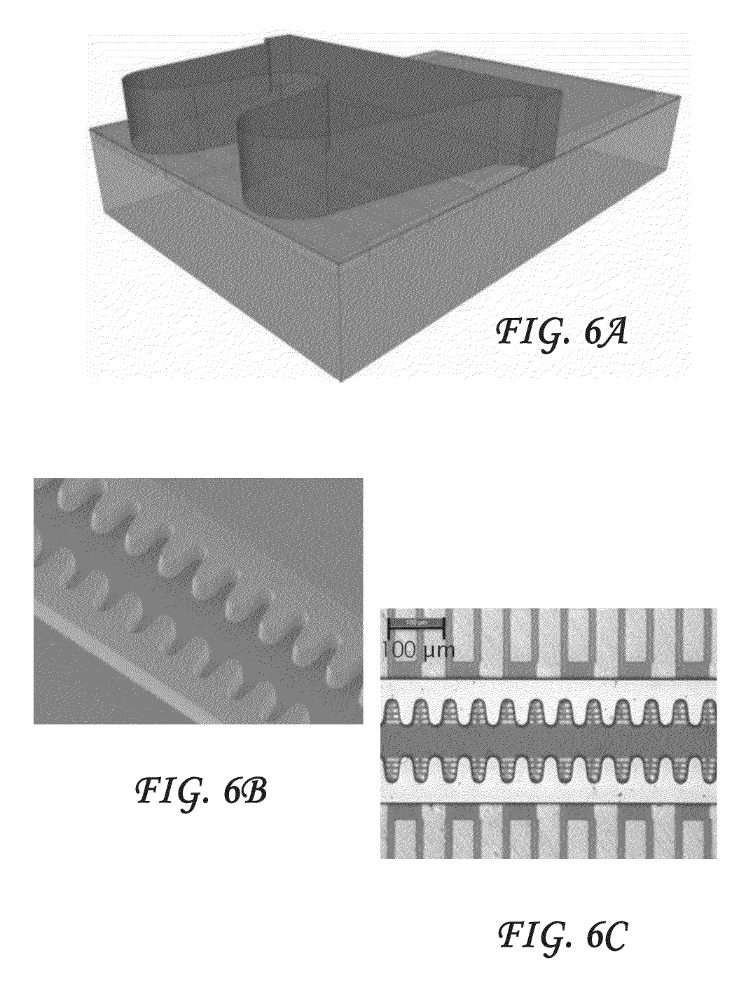

In a second stage of fabrication, labeled AA2 and BB2 in FIG. 5, an electromagnet core 525 is formed. The core 525 is formed by isolating the winding location, such as by using PECVD nitride as an isolation layer (e.g., second isolation layer 530 in FIG. 5), sputter depositing a seed layer, patterning a plating mold to form the core 525, and electroplating the core 525. The core 525 may then be smoothed, using CMP, for example, then the mold is stripped and the exposed core seed layer is stripped. FIG. 6A illustrates an example of a core in the form of a yoke. FIG. 6B is a scanning electron micrograph picture of a multi-fingered yoke fabricated for use in an undulator. FIG. 6C shows a picture of a multi-fingered yoke positioned over conductive filler in the trenches.

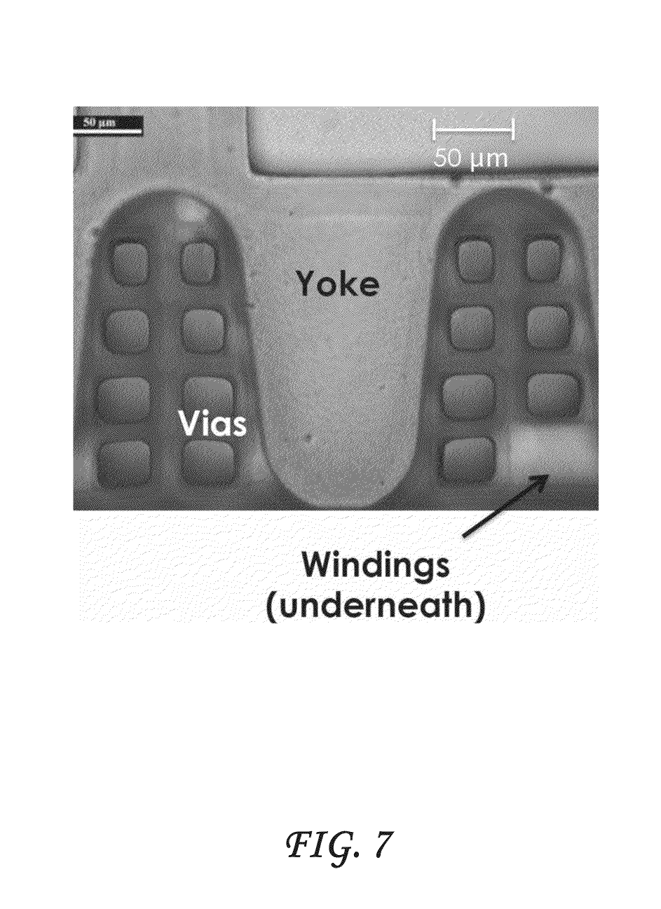

In a third stage of fabrication, labeled AA3 and BB3 in FIG. 5, vias and waveguide openings are formed in a planarizing layer. The core is isolated, such as by using PECVD nitride as an isolation layer (e.g., third isolation layer 535 in FIG. 5), structural photoresist 540 such as SU-8 is applied, and is patterned for the vias and waveguide. An etch, such as a reactive ion etch (RIE) is used to open the second isolating layer at the base of the via openings. FIG. 7 is a picture of a fabricated device after the third stage.

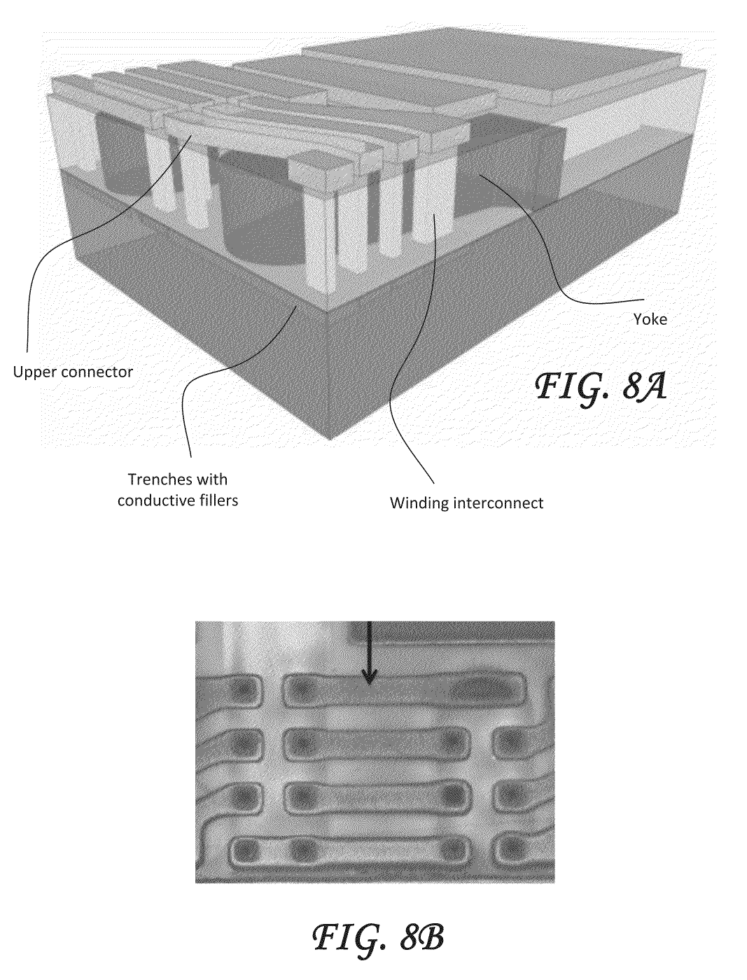

In a fourth stage of fabrication, labeled AA4 and BB4 in FIG. 5, the vias are filled to form winding interconnects 550, and the upper connectors 545 that form the top of the windings are formed. To fill the vias and form the upper connectors 545, a seed layer is sputter deposited, and a connector plating mold is patterned. A conductive filler such as goled is electroplated into the mold to fill the vias and form the upper connectors 545, and then the mold is stripped and the exposed seed layer is stripped. FIG. 8A is a conceptual drawing of the device after the fourth stage, and FIG. 8B is a picture of fabricated upper connectors after the fourth stage, such as the one pointed to by the arrow. The upper connectors 545 are electrically connected to the conductive fillers 520 by way of the winding interconnects 550 (i.e., the filled vias); thus the upper connectors 545, winding interconnects 550, and conductive fillers 520 form windings around electromagnet core 525.

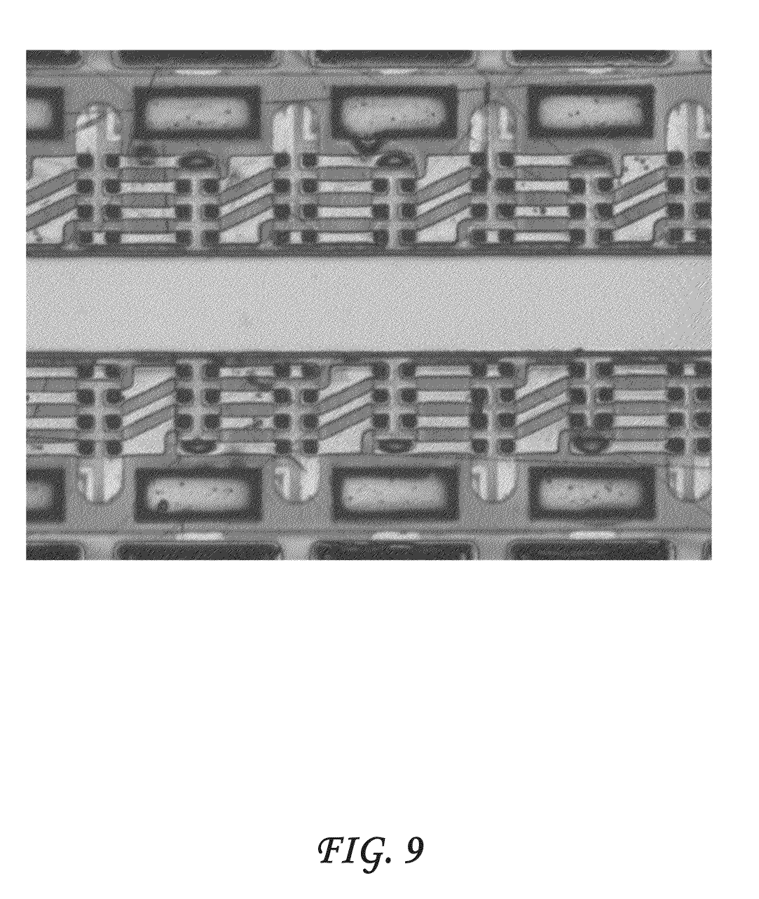

Multiple electromagnets may be fabricated simultaneously according to the techniques described in this disclosure. FIG. 9 is a top view picture of multiple electromagnets batch-fabricated according to the stages shown in the fabrication embodiment of FIG. 5. The electromagnets in the device of FIG. 9 together form an undulator.

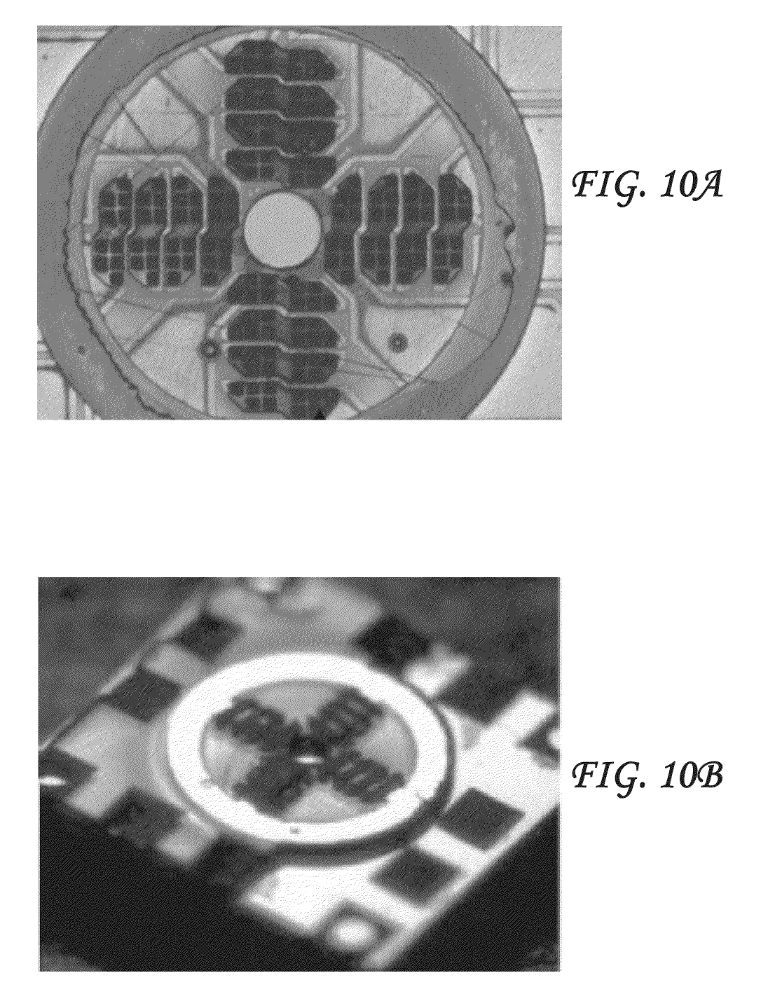

The fabrication stages described by FIG. 5 may be used to fabricate other multi-pole electromagnets also. For example, FIG. 10A is a top view picture of a quadrupole fabricated according to the stages shown in FIG. 5, and FIG. 10B is a perspective view of a quadrupole fabricated according to the stages shown in FIG. 5.

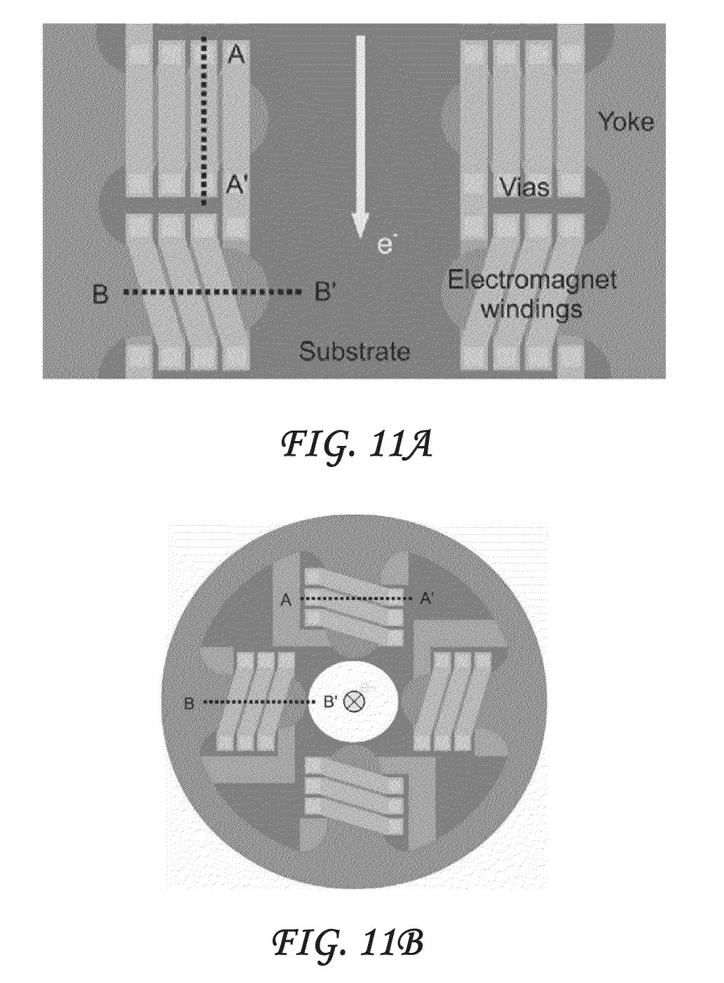

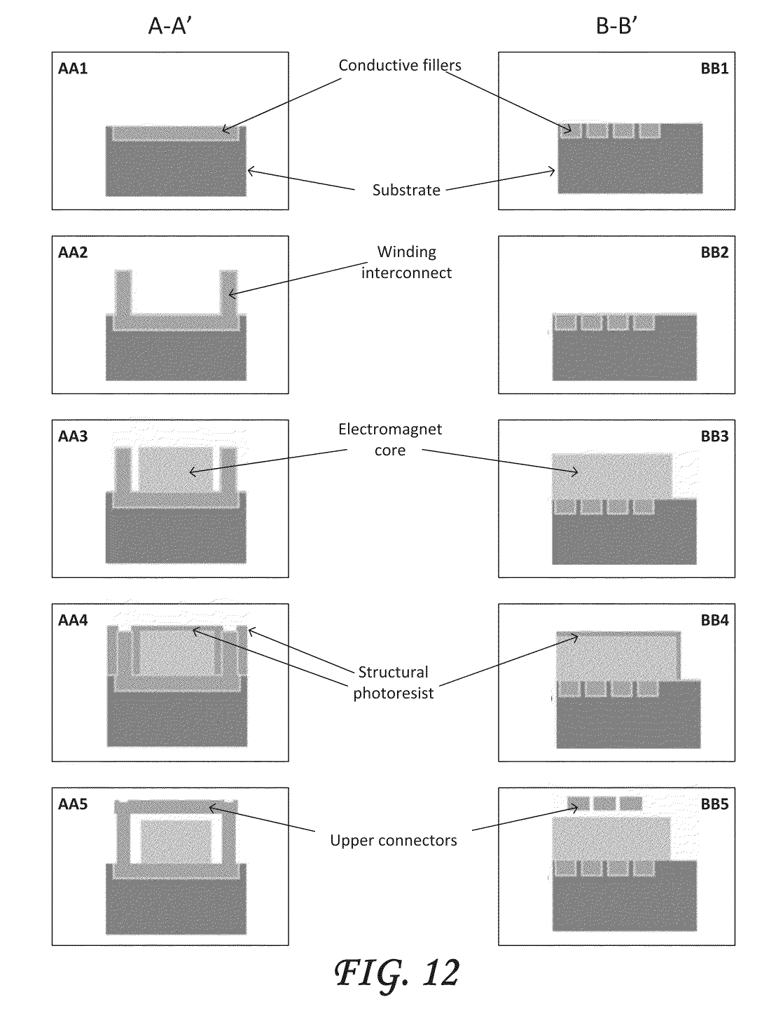

FIGS. 11A and 11B conceptually illustrate an undulator and a quadropole, respectively, for fabrication according to another, five-stage, fabrication technique in accordance with this disclosure. Each of FIGS. 11A and 11B include cross-section lines A-A′ and B-B′. FIG. 12 illustrates the five-stage fabrication in terms of the cross-sections along A-A′ (left column) and B-B′ (right column).

In a first stage of fabrication for this embodiment, labeled AA1 and BB1 in FIG. 12, a pattern for the bottom of the windings is photolithographically defined on a silicon wafer using a 5 μm thick high-aspect-ratio negative-tone photoresist (e.g., KMPR 1005, Microchem Corp., Newton, Mass., USA) and a stepper or contact aligner (e.g., Karl Süss MA6, SÜSS MicroTec AG, Garching, Germany). Using this soft mask, 20 μm deep trenches are etched in the silicon wafer using a reactive ion etching tool such as a deep reactive ion etcher (e.g., SLR-770, Plasma-Therm, St Petersburg, Fla., USA) with the Bosch process. The photoresist is removed in an organic photoresist stripper (e.g., ALEG-380, J. T. Baker, Phillipsburg, N.J., USA) and the wafer surface is cleaned in 5:1 sulfuric acid and hydrogen peroxide. A 500 nm thick silicon dioxide film (e.g., isolation layer 1 in FIG. 12) is grown by wet thermal oxidation (e.g., Tystar Mini 3600, Tystar Corporation, Torrance, Calif., USA) to electrically isolate the bottom windings from the silicon. An electroforming seed is deposited on the silicon dioxide by RF sputtering with 20 kiloVolt (kV) wafer bias (e.g., CVC 601, Consolidated Vacuum Corporation (now VEECO), Plainview, N.Y., USA). Wafer bias is used for improved coverage over the 20 μm wafer topology. The seed layer is 30 nm titanium to provide adhesion to the substrate and 300 nm copper to carry the electroplating current to provide a compatible surface for electroplating copper. The seed layer is cleaned in 1% hydrofluoric acid and a 25 μm copper film (or other conductive filler) is electroplated from a phosphorized copper anode in a sulfate based solution (e.g., Elevate Cu 6320, Technic Inc., Rhode Island, USA). The film is polished back down to the silicon surface (e.g., PM5, Logitech Ltd., Glasgow, Scotland) using a 100 nm aluminum oxide slurry (e.g., ALOX100, Universal Photonics, Hicksville, NY, USA), yielding trenches filled with conductive material (e.g., copper) that form the bottom of an electromagnet winding pattern. The wafer is cleaned of slurry with a dip in 1% hydrofluoric acid.

In a second stage of fabrication, labeled AA2 and BB2 in FIG. 12, an electroforming seed is deposited by sputtering on the surface of the silicon dioxide. The seed layer is 30 nm of titanium to provide adhesion to the substrate, 300 nm of copper to carry the electroplating current and provide a compatible surface for electroplating copper, and another 30 nm of titanium to provide adhesion between the metal and the electroplating mold. A 100 μm thick film of high sidewall-aspect-ratio negative-tone photoresist (e.g., KMPR 1025, Microchem Corp., Newton, Mass., USA) is photolithographically patterned to define the geometry of the electromagnet winding interconnects. The exposed seed layer is etched back to copper in 1% hydrofluoric acid, and 100 μm thick copper or other conductive filler is electroplated through the mold at 5 mA/cm2. The film stack is polished down using a 100 nm colloidal silica slurry to planarize the copper surface. The wafer is cleaned of slurry with a dip in 1% hydrofluoric acid. The mold is removed by plasma etching with an inductively coupled 4:1 O2:CF4 plasma (e.g., STS MESC Multiplex AOE, SPTS Technologies Limited, Newport, United Kingdom) using 600 Watt (W) coil power and 50 W platen power. The electroplating seed is stripped with a sputter etch by increasing the platen power to 200 W. A 2 μm thick insulating layer (e.g., isolation layer 2 in FIG. 12) of silicon nitride is deposited by inductively-coupled plasma enhanced chemical vapor deposition (e.g., STS MESC Multiplex CVD, SPTS Technologies Limited, Newport, United Kingdom) to isolate the bottom windings and winding interconnects from the conductive magnetic yoke.

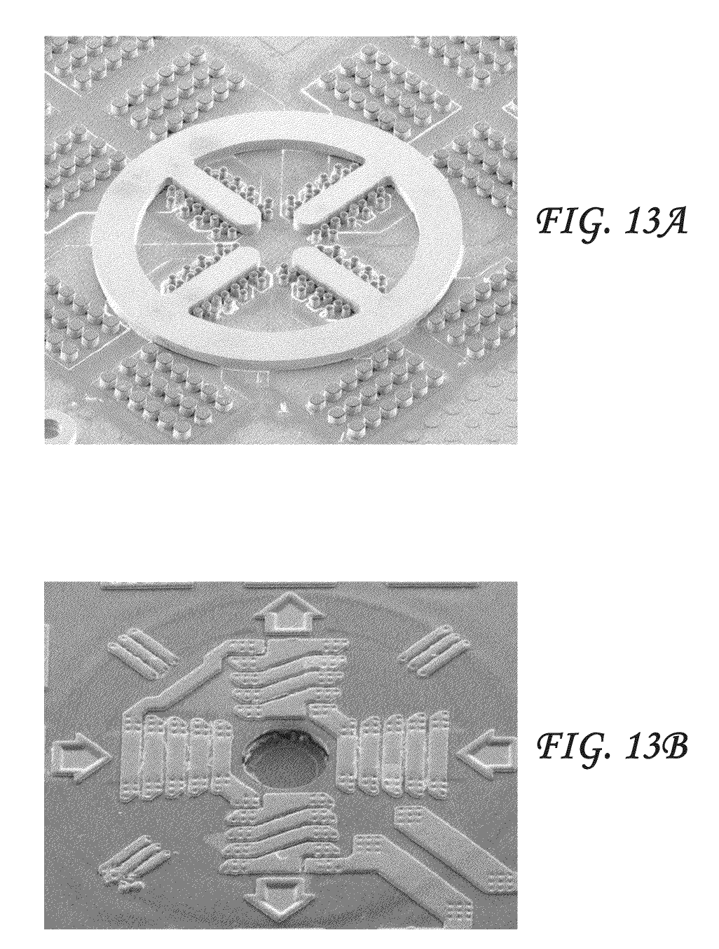

In a third stage of fabrication, labeled AA3 and BB3 in FIG. 12, an electroforming seed is deposited as described for the second stage. A 100 μm thick film of photoresist (e.g., KMPR 1025) is photolithographically patterned into the geometry of the magnet yoke. Between pouring the photoresist and spinning, the film is de-gassed in a vacuum oven at 30 Torr and 30° C. to remove bubbles. The exposed seed layer is etched to copper in 1% hydrofluoric acid, and the magnetic alloy that forms the electromagnet yoke, such as Ni₈₀Fe₂₀ or Co₅₈Ni₁₃Fe₂₉, is electroplated through the mold. The film stack is polished flat and the mold and electroplating seed are stripped as described for the second stage. FIG. 13A illustrates a 400 um gap quadrupole after the third stage of fabrication.

In a fourth stage of fabrication, labeled AA4 and BB4 in FIG. 12, a 100 μm layer of photoresist (e.g., SU-8 2025, Microchem Corp., Newton, Mass., USA) is used to provide a planar surface for defining the top layer of the coil windings. Between pouring the photoresist and spinning, the film is de-gassed in a vacuum oven at 30 Torr and 30° C. to remove bubbles. The photoresist is patterned using photolithography to define the winding interconnects and electron beam path. The film is polished flat before development using 100 nm colloidal silica slurry. The film is then annealed under vacuum for 8 hours at 200° C. The silicon nitride covering the copper in the winding interconnects is etched with an inductively coupled C₄F₈ plasma (e.g., STS MESC Multiplex AOE, SPTS Technologies Limited, Newport, United Kingdom).

In a fifth stage of fabrication, labeled AA5 and BB5 in FIG. 12, an electroforming seed layer is sputtered on the surface (e.g., CVC 601), and photoresist (e.g., KMPR 1005) is patterned into the geometry of the upper connectors of the electromagnet coil windings. Copper or other conductive filler is electroplated (e.g., Elevate Cu 6320) through the photo-patterned mold to form the upper connectors; the upper connectors, winding interconnects, and filled trenches form windings. The mold and electroplating seed are stripped using the process described above. FIG. 13B illustrates a 200 um gap quadrupole after the fifth stage of fabrication.

Device testing under vacuum in an electron beam has shown that it may be preferable to remove the SU-8 photoresist to prevent damage during operation (as illustrated in the fifth stage of fabrication). The SU-8 may be etched back using the plating mold stripping process described above.

For the quadrupole, holes are etched from the back of the substrate to the front, defining the quadrupole gap, using a post-process Bosch etch (e.g., Versaline Fast Deep Silicon Etch II, OC Oerlikon, Pffiffikon, Schwyz, Switzerland). The etch pattern is defined (e.g., KMPR 1005) on the back-side of the wafer and aligned to the front (e.g., using a Karl Süss MA6).

Magnetic field strength is limited either by magnetic saturation or electromagnet current. Saturation of the electromagnet core (or yoke) at locations away from the pole tip can be addressed by tapering the pole width, which can both accommodate flux from multiple poles and compensate for fringing magnetic field. Increased yoke thickness will reduce the portion of field lost to fringing, but adds interface stress. Electromagnet current is limited by electromigration or power dissipation. For copper windings, electromigration limits reliable operation to 10⁶ A/cm² current density, while acceptable power dissipation is a function of package cooling. Both current limitations are improved with increased winding cross-section. Four turns per winding with a 1600-μm² winding cross-section was found to be an optimized design.

In a third embodiment of an electromagnet fabrication technique, a result is an extension of the free-space fields of microfabricated electromagnets from the <0.001 mm³ volume of air gap fields in prior planar and solenoidal MEMS electromagnets to a 0.2 mm³ free-space volume exceeding 20 mTesla intensity. This fabrication technique embodiment involves stages such as vacuum baking between pouring photoresist, and spinning to remove gas trapped by the high-aspect ratio metal structures, four-electroplating-step metallization, defining vias before the curved yoke to avoid stray exposure at the focal point of concave features, and etching using sequential dry and wet processes to finish etches near metal where ion shading has reduced the etch rate.

In the third embodiment of electromagnet fabrication techniques, a pattern for the bottom of the windings is photolithographically defined on a silicon wafer using 5 μm thick photoresist (KMPR 1005) and an aligner (e.g., Karl Süss MA6). Using this soft mask, 20 μm deep trenches are etched in the silicon using a deep reactive ion etcher (Plasma-Therm SLR-770). The photoresist is stripped in heated ALEG-380 and 5:1 sulfuric acid:hydrogen peroxide. A 500 nm SiO₂ film is grown by thermal oxidation (e.g., Tystar Mini 3600) to isolate the bottom windings from the silicon. An electroforming seed is deposited on the SiO₂ by RF sputtering with 20 kV wafer bias (e.g., CVC 601). The seed layer is 30 nm Ti for adhesion to the substrate and 300 nm copper to carry the electroplating current. Seed layer oxidation is etched in 1% hydrofluoric acid, and a 25 μm copper film is electroplated from a phosphorized copper anode in a sulfate based solution (e.g., Technic Elevate 6320) at 5 mA/cm². The wafer is polished to silicon with chemical mechanical polishing, CMP, (e.g., Logitech PM5) using 100 nm alumina slurry, yielding filled trenches, which will be the winding bottom layer inlayed in the substrate.

In the third embodiment of electromagnet fabrication techniques, for the winding vias, electroforming seed is sputter deposited, with an additional 30 nm layer of titanium for adhesion between the seed and an electroplating mold (i.e., Ti/Cu/Ti layer). A 100 μm high aspect ratio photoresist (e.g., KMPR 1025) film is patterned to define the electromagnet winding's interconnect geometry. The titanium exposed by the photoresist pattern is etched back to copper in 1% hydrofluoric acid, and 100 μm of copper is electroplated through the mold. The winding interconnect height is planarized by CMP. The slurry is removed with a dip in 1% HF. The mold is removed by plasma etching with 4:1 O₂:CF₄ plasma (STS AOE) using 600 W coil and 50 W platen power. The electroplating seed is stripped with a sputter etch and dips in 5% acetic acid and 1% hydrofluoric acid, and a 2 μm insulating silicon nitride film is deposited by plasma enhanced chemical vapor deposition, PECVD, (e.g., STS Multiplex CVD) to isolate the windings from the magnetic yoke.

In the third embodiment of electromagnet fabrication techniques, for the magnetic core, an electroforming seed is deposited as described with respect to the bottom winding layer fabrication. A 100 μm film of photoresist (e.g., KMPR 1025) is patterned into the geometry of the core. Between pouring the photoresist and spinning, the film is de-gassed in a vacuum oven at 30 Torr for 30 sec. The exposed seed layer is etched to copper in 1% hydrofluoric acid, and a magnetic alloy (e.g., Ni₈₀Fe₂₀ core, Bsat=1.1 Tesla, pᵣ=8000) is plated through the mold. Planarization, mold and seed stripping, and layer isolation proceed as described with respect to the winding via layer fabrication. A 100 μm film of structural photoresist (e.g., SU-8 2025) is used to provide a planar surface for defining the top of the coil windings. The SU-8 is de-gassed in the same manner as KMPR described above, patterned and baked to expose the winding vias, and planarized to 10 μm above the yoke before development to improve thickness uniformity. The film is then annealed in vacuum for 8 hours at 200° C.

In the third embodiment of electromagnet fabrication techniques, for the top winding layer, copper in the vias is exposed by etching the silicon nitride with C₄F₈ plasma (e.g., STS AOE). A seed layer is sputtered on the surface as described with respect to the bottom winding layer fabrication. A 25 μm photoresist layer (e.g., KMPR 1005) layer is patterned into the geometry of the top winding layer, and 20 μm copper is electroplated through the mold. The mold and seed are stripped using the process described with respect to the bottom winding layer fabrication. The structural photoresiste is etched using the mold stripping process described, to avoid thermal expansion issues during operation.

Through-wafer holes are desirable in some applications, such as manipulation of charged particle beams. To achieve a through wafer particle path, an etch pattern may be defined with photoresist (e.g., KMPR 1005) on the back-side of the wafer and aligned to the front using a contact aligner (e.g. Karl Süss MA6) or stepper. Holes and trenches are etched from the back of the substrate to the front, defining the electromagnet gap and singulating the devices using a post-process Bosch etch (e.g. Oerlikon FDSE II).

A 4-pole electromagnet manufactured according to the third embodiment of electromagnet fabrication techniques was tested. The electromagnet was mounted in a conventionally machined copper fixture with a mechanically retained PCB (Rogers Duroid 6002) and wirebonded with 15 μm Al wires. The electromagnet die withstood 70 A pulses on a probe station without failure, but the 15 μm diameter Al wirebonds used to package the electromagnets failed at 5.5 A.

Measuring the micro-scale field distribution was challenging due to the size scale of the electromagnet bore. The field can, however, be inferred from simulations correlated to impedance measurements of the electromagnet. Each electromagnet was measured using an impedance analyzer (Agilent 4294A) with a set of coaxial probes (APT 740CJ) in a four-terminal pair configuration. Before packaging, the electromagnets had 58.2+1.2-mΩ resistance and 30.4±1.9-nH inductance at 100 kHz. The field produced by −1.0 A in each coil of the multi-pole electromagnet was simulated using the finite element method multiphysics software COMSOL Multiphysics.

The inductance calculated by integrating the stored magnetic energy (E=f B²/2μ dv) matched the measured inductance within 6% before packaging and 21% after packaging. Post-packaging measurements were through 20 wire bonds reworked with a chlorine plasma etch, potentially explaining the variation between measurements. Simulations show that the yoke for the electromagnet as-fabricated saturate with I=+2.0 A drive current when producing a dipole field, while the poles are only 25% saturated with magnetic field. The yoke width in these devices was limited by a 3-mm die size, limiting the maximum field. A 4× field strength improvement could be realized by simply extending the yoke width without further optimization.

A 4-pole electromagnet manufactured according to the third embodiment of electromagnet fabrication techniques was mounted in the path of an electron beam and powered in a dipole configuration to demonstrate particle beam steering. By varying the electrical current in each coil, the electron beam was steered across an imaging system. Using a different set of currents, the electromagnet can steer and focus the beam in any direction. The experiment used an electron beam generated by photoelectric effect using a UV laser and accelerated with an electric field. A solenoid electromagnet adjusts beam focus exiting the electron gun and a set of steering electromagnets adjusted position and angle. After a drift length, a chamber housed the electromagnet, and after another 11.5-cm drift length, an imaging system composed of a Z-stack micro-channel plate (MCP) intensifier, phosphor screen, and cooled CCD camera (Hamamatsu Flash 2.8) was used to measure the beam position and shape. The electromagnet was mounted behind a 50 μm fixed iris and probed with a 34-keV electron beam. Each measurement included 20 images, calibrated by subtracting an image of the MCP with the beam blocked. Electromagnet current was stepped from −4 A to +4 A in an x-deflecting configuration. The experiment demonstrated 0.01 Tesla/A dipole field and 686 μm effective magnetic length, matching FEM simulation within the alignment accuracy of the iris.

Three-dimensional (3-D) FEM simulations indicate that the field exceeded 20 mTesla over 0.2 mm³ free-space volume. The larger usable field volume extends the range of the electromagnets fabricated according to this disclosure to new applications such as charged particle beam optics.

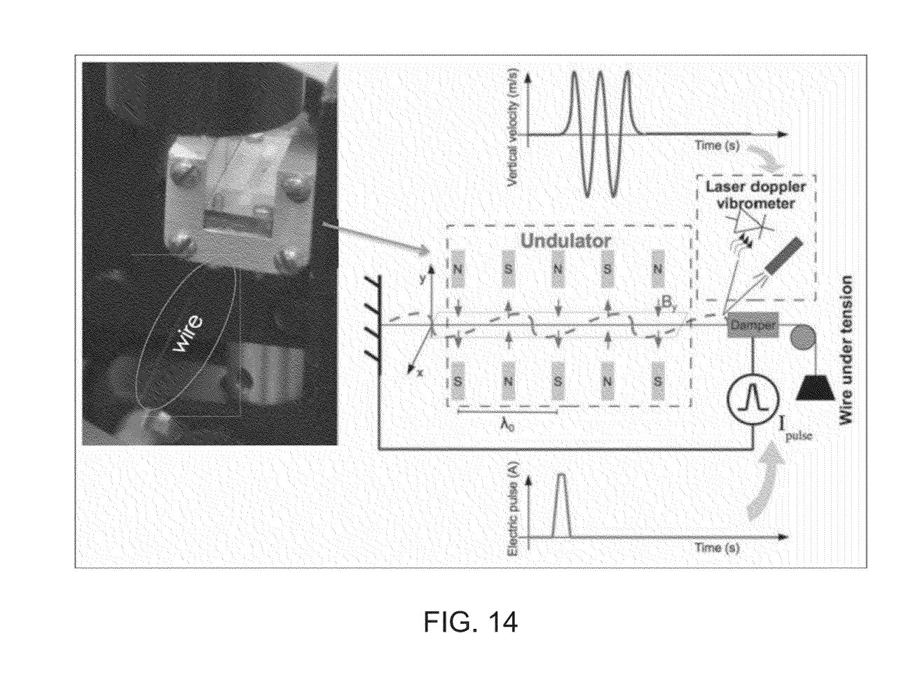

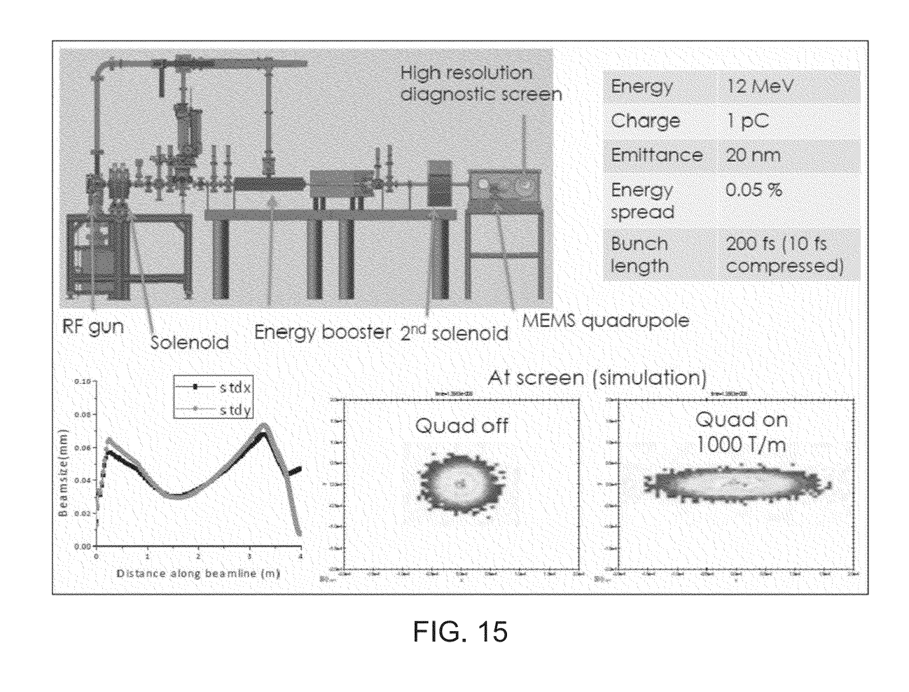

Characterization of an electromagnetic structure fabricated in accordance with this disclosure may be performed as follows. Electrical characterization may be performed using an impedance analyzer to measure impedance of a device under test (DUT). Magnetic characterization may be performed using magnetic microscopy, or by using a nuclear magnetic resonance probe (NMR), where the NMR probe is swept down the undulator gap, for example. Alternatively, FIG. 14 illustrates a setup for magnetic characterization using pulsed wire measurement to characterize an undulator, for example. Optical characterization may be performed, such as by using a Pegasus beamline. By way of example, FIG. 15 illustrates test setup and results of an optical characterization of a quadrupole fabricated according to the fabrication stages illustrated in FIG. 5.

Further to the examples provided above for characterization of the micro-machined electromagnets, additional examples and details are next provided as related to tests performed on manufactured devices.

Electrical characterization: The impedance of an electromagnet (e.g., the impedance of each quadrupole electromagnet and undulator period electromagnet) may be measured using a Precision Impedance Analyzer (e.g., 4294A, Agilent Technologies, Westlake Village, CA, USA) with a set of tungsten coaxial probes (e.g., 740CJ, American Probe Technologies, San Jose, Calif., USA) in a four-terminal pair configuration prior to singulating (e.g., singulating the quadrupoles or undulators) from the silicon wafer. The impedance analyzer can resolve no less than 1 mΩ resistance and 1 mΩ reactance, so proper shielding and calibration of the probes is used to take measurements. Each period in the undulators designed for use with an electron beam are connected in series, so individual electrical undulator measurements were taken from single period test structures with 25 μm gaps for matching with simulations. 3-D magnetostatic simulations of the quadrupoles and undulators were performed using the finite element method in COMSOL Multiphysics with 2 A (320 kA/cm²) undulator drive current and 5 A (200 kA/cm²) quadrupole drive current. The static field and field gradient were recorded, and the inductance was calculated from the total magnetostatic energy of the system using the formula E=½ LI². Table 1 lists the electrical measurement, simulation results, and implied peak magnetic field.

TABLE 1

| | | | Implied field/ |
|---|---|---|---|
| | Measurement | Simulation | Field gradient |
| λₐ = 400 μm g = 25 μm undulator | 137 ± 1.0 mΩ, 17.0 ± 2.0 nH | 17.7 nH | 0.690 T |
| 600 μm gap quadrupole | 58.2 ± 1.2 mΩ, 30.4 ± 1.9 nH | 32.2 nH | 1400 T/m |

Magnetic characterization: Nuclear magnetic resonance (NMR) frequency can provide a clear measurement of the local magnetic field. The frequency associated with protons transitioning between spin states in a magnetic field is 42.57 Megahertz (MHz)/Tesla. Using NMR, absolute field and field gradient can be measured across a volume. A convenient source of protons and the RF stimulation and measurement is water molecules drawn into a capillary tube and a RF coil etched around the tube circumference. To accomplish this, 10 μm of copper were metalized on 100 μm outer diameter, 80 μm inner diameter quartz capillary tubes and had coils milled on an ultraviolet laser lather (e.g., Laserod, Torrance, Calif., USA). Because there is a limited number of protons in the bore of a micro-coil, and just a small fraction of the protons relax from an excited state for each measurement, there must be sufficient signal to overcome the noise in the measurement circuit. The signal-to-noise ratio (SNR, or S/N) of the proton relaxation measurement in a micro-coil may be represented as S/N∝nB^{3/2}t^{1/2}/(4k_{b} [symbol] Δf)^{1/2}, where n is the number of nuclear spins, B is the magnetic field, t is the observation time, k_{b} is the Boltzmann constant, R is the coil resistance, T is the temperature, and Δf is the frequency bandwidth. Experimental results indicate that SNR exceeding 5000 will be achievable for this measurement at room temperature with a 1 Tesla field, 1 second integration time, and 1 kilohertz (kHz) measurement bandwidth at room temperature.

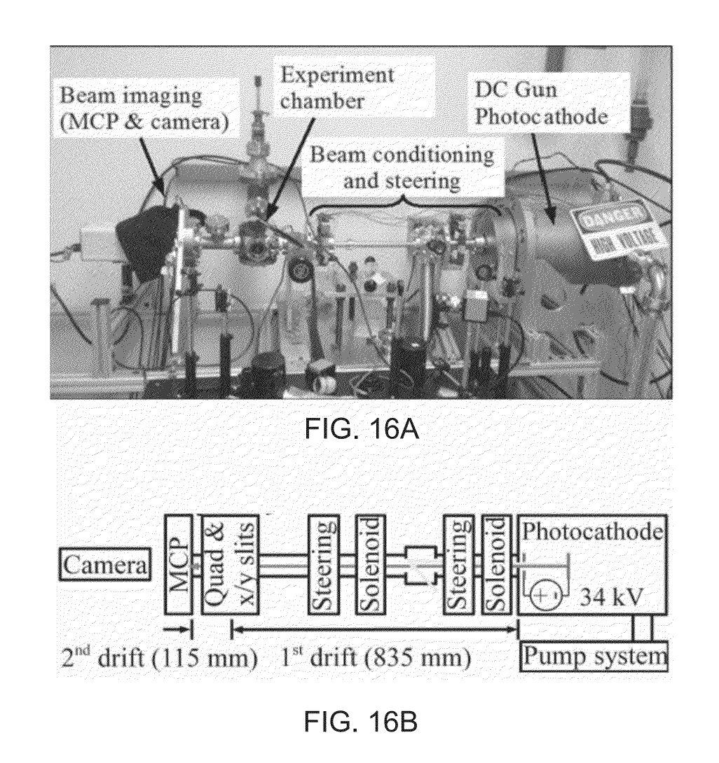

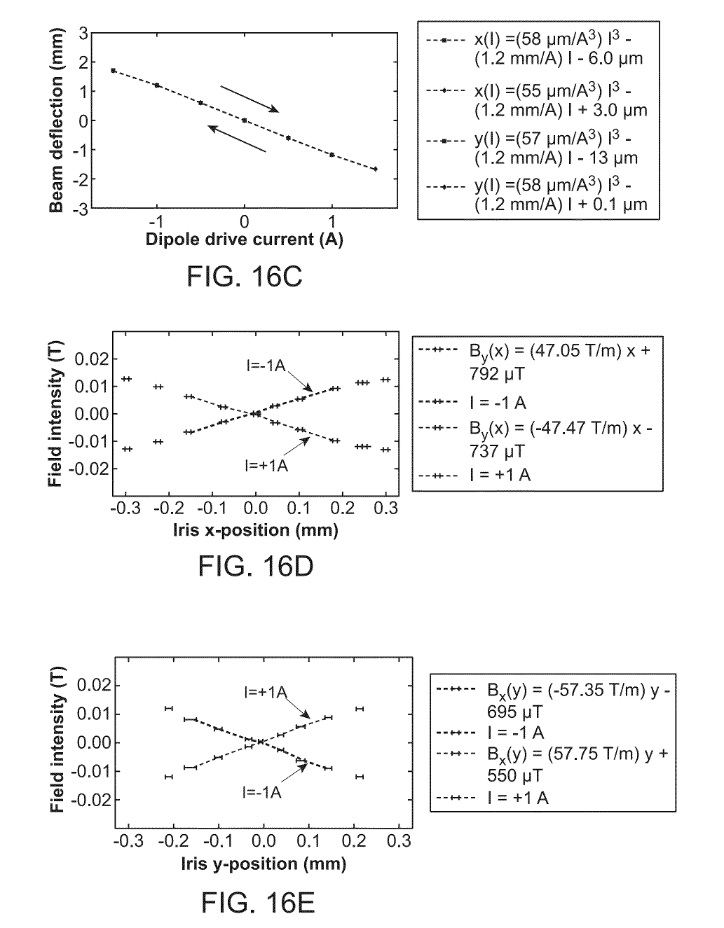

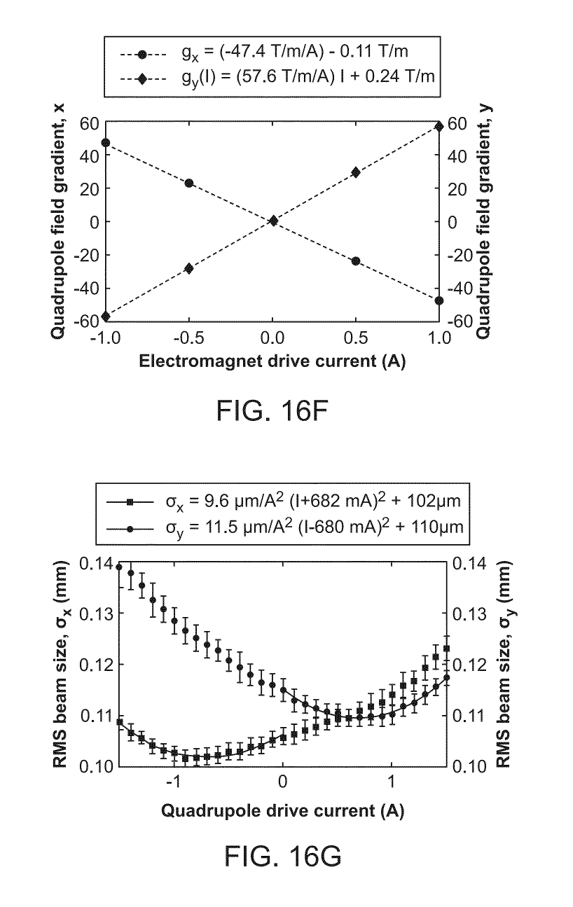

Low-energy beam test: Electromagnets manufactured according to techniques of this disclosure were subjected to low-energy beam tests. A goal of an early low-energy beam test was to provide initial data on the response of the electron beam to the dipole and quadrupoles field. The tests were planned with no heat-sink attached to the device, expecting some focusing before the heating ruptured the structural polymer in the quadrupoles and dipoles (SU-8). The early versions of the quadrupoles and dipoles were tested using a static-field photogun setup, shown in FIG. 16A. Holes were deep reactive ion etched in the individual dipoles and quadrupoles, and the device dies were mounted on PCB boards and wire-bonded to provided contacts for 2-port coil energizing. A 25 keV electron beam was directed through the hole and the coil was energized. The early fabricated devices had much higher resistance than designed (20Ω rather than 0.1Ω) leading to substantial Ohmic heating. This led to rapid expansion of the SU-8 structural polymer (52 ppm/° C.) and permanent open circuits in the quadruple and dipole windings. This initial test led to the incorporation of an SU-8 etch-back stage in the fabrication process subsequent to the completion of the coil. A later low-energy beam test used a multi-pole electromagnet and a static-field photogun setup to demonstrate steering and focusing of an electron beam. The experiment setup is shown in FIG. 16.

Electromagnets manufactured according to techniques of this disclosure were subject to further low-energy beam tests. A goal of this low-energy beam test was to demonstrate steering and focusing and to map the quadrupole magnetic field across the 600 μm gap of the electromagnet. The electron beam used in this experiment was generated using a short UV laser pulse illuminating a photocathode embedded in a static electric field (DC photogun). A solenoid electromagnet was used to adjust the beam focus exiting the photocathode, and a set of steering electromagnets used to position and angle during an 835 mm drift length to an experiment chamber. The chamber housed the MEMS quadrupole behind a pair of micrometer-mounted orthogonal 0.02-mm slits (e.g. Thorlabs S20R) that have been stripped of anodizing and iron oxide coatings to form an electron beam aperture. After another 115 mm drift length, an imaging system composed of a Chevron micro-channel plate (MCP) intensifier, phosphor screen, and cooled CCD camera (Hamamatsu Flash 2.8) recorded the beam position and shape. The experiment setup is shown in FIG. 16A, with a block diagram of the setup shown in FIG. 16B. A background shot was acquired with the electron beam turned off for each image, and the background shot was subtracted from the data before calculating beam centroid and root mean square (RMS) size. The experiment used a slightly under-focused 34 keV sub-pC electron beam pulsed at 960 Hz repetition rate. The iris central position was obtained by switching the MEMS electromagnet on and off in quadrupole configuration and adjusting the position until the beam location did not change. Each measurement consisted of 25 images taken with 250 ms exposure time.

Low-energy beam test for steering: To measure beam steering performance, the electromagnet current was stepped from −1.5 A to +1.5 A and back to −1.5 A in 0.5 A increments in an x-dipole field configuration (two adjacent poles energized as North and two adjacent poles energized as South) and then repeated in a y-dipole configuration. FIG. 16C shows measured data for the beam centroid steered right, left, down, and up. Steering the 34 keV electron beam with the electromagnet configured in dipole mode at 1 A resulted in a 1.2 mm deflection after a 115 mm drift distance, corresponding to a 10.8 mTesla dipole field using the small angle approximation. Electromagnet hysteresis when changing steering directions and third order nonlinear coefficients measurements were at the limits of the experiment resolution (0.042 mm).

Low energy beam test for quadrupole field mapping: Field uniformity experiments were taken in quadrupole configuration (adjacent poles energized as opposite polarities) from −1 A to +1 A current in 0.5 A increments. For each electromagnet current dataset, the iris was stepped in equal intervals across the entire electromagnet bore. The magnetic field value was obtained by measuring the electron beam steering at each iris position and using the effective magnetic length from FEM simulations. FIGS. 16D and 16E show the resulting field gradient across the X-axis transverse direction (FIG. 16D) and Y-axis transverse direction (FIG. 16E) calculated from the measurements. An approximately 54 Tesla/m field gradient at approximately 1 A was expected from FEM simulation and 47 Tesla/m and 57 Tesla/m were measured across the x and y-axis, respectively. The field gradient, shown in FIG. 16F, scales linearly with current, as expected. Measured hysteresis is less than the measurement variance. The difference between the horizontal and vertical field gradient could be due to poor control of the quadrupole electromagnet axis in the experimental chamber. The experiment setup obstructed observation of electromagnet orientation inside the chamber and the azimuth angle was hand-set to pass the beam. The quadrupole was reoriented between the quadrupole field mapping and electron beam focusing experiment. Simulations indicate that a 20° azimuth error in the experiment would reduce the effective magnetic length on the beam path, producing the reduced field gradient measurement shown in FIG. 16D.

Low-energy beam test for focusing: The measured field gradient and RMS beam width at different electromagnet currents can be used to calculate beam parameters in a quadrupole scan measurement, demonstrating that the MEMS quadrupoles work as conventional magnetic optics. To measure the performance of the quadrupole focusing the beam, the electromagnet current was configured for quadrupole mode and stepped from −1.5 A to +1.5 A and back to −1.5 A in 0.1 A increments. The measured beam RMS width is shown in FIG. 16G, and a focused beam waist is obtained at the MCP plane in the y-axis for I=0.9 A and in the x-axis for I=−0.9 A. The beam expands slightly between the first (horizontal) and second (vertical) slit, resulting in the small observed asymmetry. The data can be fitted using the gradient extracted from the beam steering measurements to obtain an estimate for the beam phase space parameters at the quadrupole entrance. Using the transfer matrix of a thin quadrupole of focal distance f and drift length l_{d} between the quadrupole and MCP screen, and representing the electron beam with its transverse phase space parameters (x for position, x′ for momentum or angular deviation in the small angle approximation, and

∈=\sqrt{ [symbol]xx [symbol] [symbol] x′x′ [symbol] − [symbol] xx′ [symbol] ²}

for RMS emittance) in the small angle approximation, the final RMS beam size σ_{x,f}²=var(x_{f}) in the transverse horizontal axis can be written as:

$${σ}_{x , f}^{2} = {( 1 - \frac{{l}_{d}}{f} )}^{2} {σ}_{x}^{2} + {l}_{d}^{2} + {l}_{d}^{2} {σ}_{{x}^{′}}^{2} + 2 {l}_{d} ( 1 - \frac{{l}_{d}}{f} ) {σ}_{{xx}^{′}}$$

The beam parameters at the quadrupole from the fit of the experiment data yield RMS beam width σₓ=0.017 mm, σ_{y}=0.021 mm and angular divergence σ_{x′}=0.9 mrad, σ_{y′}=1.0 mrad, which is in good agreement with the beam parameters expected following the 20 μm iris and validates the model for the MEMS quadrupole performance.

High-energy beam test: Electromagnets manufactured according to techniques of this disclosure may be subjected to high-energy beam tests, for example on an ultra-low emittance 12 MeV PEGASUS beamline, to characterize the electron beam after passing through the undulators and quadrupoles and to characterize the radiation produced by the undulator. This test demonstrates the feasibility of both surface micro-machined undulators and focusing optics in a medium-energy beam, in addition to characterizing the performance of the devices with the well-studied beam. An undulator may be held in place on a copper block with water-cooling channels in a vacuum chamber attached to the PEGASUS beamline, where the cooling block itself is attached to a precision 4-axis optical mount (x-axis, y-axis, pitch and yaw). The 4-axis adjustments may be computer controlled by 0.05 μm precision 0.2 μm repeatable in-vacuum servo-actuators (e.g., Z812V, Thorlabs, Newton, N.J., USA) for repeatable alignment with the ultra-low-emittance beamline.

Magneto-static 3-D finite element method (FEM) simulations of magnetic the field were performed using COMSOL Multiphysics. Simulated geometries were designed to fit within the available manufacturing limits. Table 2 details the results. The first row entry in the table (in bold) indicates one device that was also manufactured. The geometries were optimized for peak gradient. In the table, magnet gap refers to the distance between the electro-magnet pole tips, yoke length refers to the physical length of the quadrupole device, peak field gradient refers to the transverse magnetic field gradient along the longitudinal axis of the electromagnet driven to yoke saturation, and effective magnetic length refers to the normalized interaction distance of the particle beam in the field gradient (effective magnetic length Lₘ=∫g dz/gₚₑₐₖ).

TABLE 2

| Magnet | Yoke | Peak field | Effective |
|---|---|---|---|
| gap | length | gradient | magnetic length |
| 0.6 mm | 0.055 mm | 253 T/m | 0.477 mm |
| 0.6 mm | 0.200 mm | 1000 T/m | 0.532 mm |
| 0.4 mm | 0.200 mm | 2200 T/m | 0.414 mm |
| 0.2 mm | 0.200 mm | 6100 T/m | 0.274 mm |
| 0.1 mm | 0.200 mm | 10000 T/m | 0.240 mm |

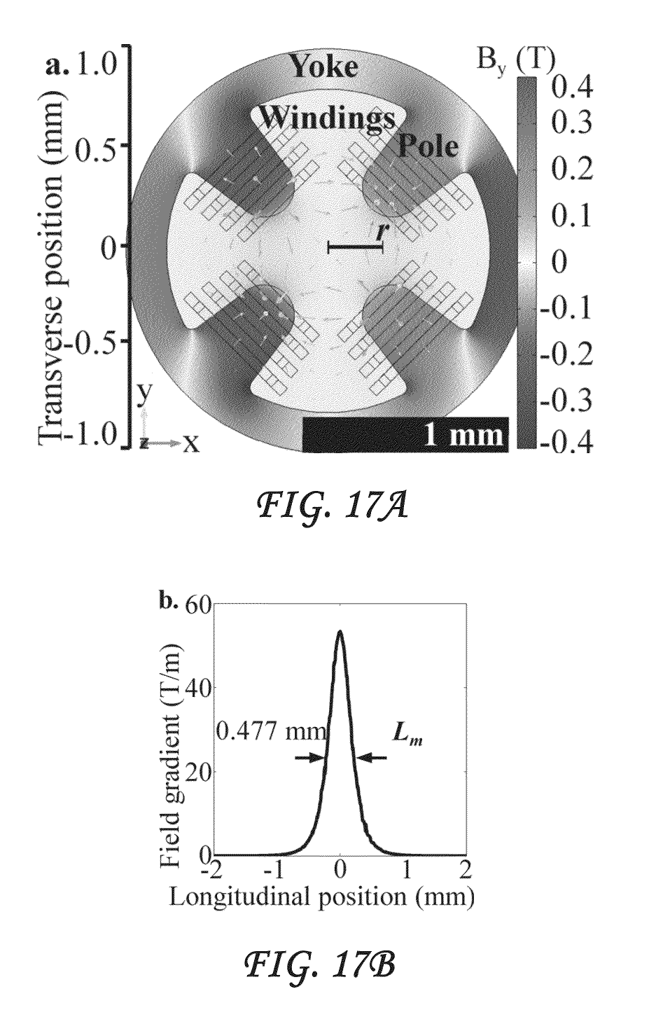

By way of example, FIGS. 17A and 17B illustrate the results of a simulation of magnetic flux in the gap of a micro-machined quadrupole driven by 1 A. FIG. 17A illustrates a transverse (y-axis) quadropole magnetic field for I=1 A in a 4-pole electromagnet, where the arrows show the 3-D direction of the magnetic field. FIG. 17B is a plot of quadrupole field gradient (dB_{y}/dx) along the longitudinal axis in the center of the 4-pole electromagnet for I=1 A.

Many applications using particle beams require beam optics with a consistent field over the usable aperture and small undesired higher-order field content. The short yoke length and narrow electromagnet gap of a micro-machined quadrupole electromagnet results in varying multi-pole coefficients as the electron traverses the focusing optic. Multi-pole analysis was performed on data from the 3-D FEM simulation shown in FIGS. 17A, 17B to extract the quadrupole and higher order transverse field components for longitudinal slices of the magnetic field. A good field region for the fabricated 0.6 mm-gap electromagnet, where the multi-pole coefficients from sextupole to hexadecapole integrated down the longitudinal axis are less than 0.1% of the on-axis quadrupole field, was calculated using the multi-pole analysis from FEM simulation. Table 3 details the multi-pole analysis results for the fabricated quadrupole electromagnet (first row entry, in bold), along with four quadrupole electromagnet designs optimized for peak gradient. Good field region refers to the diameter of the usable electromagnet bore, 4-pole refers to the quadrupole field gradient for the electromagnet driven by 1 A, and 6-pole and 8-pole list the relative intensity of the sextupole and octupole field components, respectively, evaluated at the good field region edge for the electromagnet driven by 1 A. Higher-order multi-pole field content was strongly correlated to the shape of the yoke pole tips, with octupole field content increasing dramatically as the hyperbolic-shaped tip width was truncated in smaller-gap electromagnets to provide space for the electromagnet windings.

TABLE 3

| Magnet | Yoke | Good field | | | |
|---|---|---|---|---|---|
| gap | length | region | 4-pole | 6-pole | 8-pole |
| 0.6 mm | 0.055 mm | 0.141 mm | 54 T/m | 8 × 10⁻⁵ | 8 × 10⁻⁴ |
| 0.6 mm | 0.200 mm | 0.188 mm | 118 T/m | 9 × 10⁻⁵ | 3 × 10⁻⁴ |
| 0.4 mm | 0.200 mm | 0.136 mm | 308 T/m | 1 × 10⁻⁴ | 7 × 10⁻⁴ |
| 0.2 mm | 0.200 mm | 0.068 mm | 993 T/m | 1 × 10⁻⁴ | 8 × 10⁻⁴ |
| 0.1 mm | 0.200 mm | 0.021 mm | 3 kT/m | 9 × 10⁻⁵ | 6 × 10⁻⁴ |

The low impedance (58 mΩ, 30 nH) of the micro-fabricated electromagnets facilitates circuit-limited driving frequencies up to 2 MHz, allowing pulse-to-pulse reconfiguration of the magnetic field, or short duty cycle operation. Driving the electromagnet windings with short duty cycle current pulses dramatically reduces the average power dissipated by the electromagnet and relaxes the thermal constraints on the electromagnets. The expected average power dissipation of the micro-fabricated quadrupole electromagnet driven by 1 A pulses at 960 Hz for pulse widths between 1 μs and 1 ms (0.1% to 96% duty cycle) was calculated using the measured impedance of the 0.6 mm gap electromagnet up to 1 MHz. Despite the increased dissipation due to skin effect and eddy current losses, reducing the duty cycle to 0.1% reduces power dissipation by a factor of greater than 750, allowing more than 25 times the drive current compared to continuous operation.

While yoke thickness up to 100 μm has been demonstrated, thicker films may be introduced to reduce magnetic flux leakage in the undulator and provide greater magnetic length for the quadrupoles. Achieving mm-scale magnetic length for the quadrupole and 200 μm yoke thickness for the undulator, along with dynamic field diagnostic and tuning strategies, enables a new class of performance in manipulating electron beams in the size scale between 100 μm and 1 mm.

Thus has been described micro-fabricated electromagnets, with embodiments of fabrication techniques and examples of characterization methodologies. Electromagnets may be combined into undulators, quadrupoles, sextupoles and the like, which are envisioned, for example, as insertion devices and focusing lattices for compact light sources. Toward this end, 400 μm and 600 μm quadrupole magnets have been designed to complement the accelerator technology being developed by the GALAXIE project, a harmonic-focusing high-gradient accelerator. Short period undulators have been fabricated to enable the production of high-brightness, high-energy light from low to moderate energy beams. To demonstrate, an experiment has been set up to send an ultra-low emittance 12 MeV electron beam (PEGASUS beamline) through a 100 μm gap 400 μm period undulator to investigate bunching of the beam and detect the 431 nm light produced by the undulator.

Micro-scale magnetic quadrupole focusing magnets and undulators also enable scaling of x-ray free electron lasers (XFELs). Recently developed XFELs generate x-rays with high brightness and coherence by accelerating focused electrons and converting their kinetic energy into synchrotron radiation using the sinusoidal magnetic field of an undulator. However, the size and rarity of existing XFELs prevent their widespread use. Miniaturized XFELs could enable broad access to phase contrast x-ray imaging, which has the potential to decrease X-ray dosage by a factor of 100, and improve resolution of soft tissues by a factor of up to 1000, over conventional X-ray imaging.

Surface-micromachining technology may be used to batch manufacture multi-pole electromagnets with sub-μm precision. The precision allows for generation of high gradient fields. For example, because the magnetic field gradient in a quadrupole lens scales inversely with the gap between the pole tips, a sub-mm gap quadrupole enables multi-kilo Tesla per meter (kT/m) gradients and β<10 cm focusing lattices.

A device including multiple multi-pole electromagnets may include a control system for directing the field generated by the device. Further, a device including multiple multi-pole electromagnets may include a control system allowing for separate control of individual electromagnet windings or groups of windings. The control system may be external to the device or internal to the device, may include mechanical and/or electrical components, and may further include software or firmware. The control system may be implemented in hardware, software, or a combination of hardware and software. Portions or all of the control system may be implemented as an integrated circuit.

Selective controllability allows for rapid configuration for a specific use, adaptation to a changing environment, calibration during use, and fast modification of a generated field, among other benefits.

The windings of electromagnets may be controlled individually or in groups to configure an n-tupole device. For example, windings may be controlled such that a quadrupole may be configured to function as an ocotpole, a quadrupole or a dipole, and the intensity of the fields developed may be controlled by control of the current through the windings. In one embodiment, several quadrupoles are combined into a beam-manipulation device, with selective control of the electromagnet windings. Beam manipulation includes but is not limited to beam focusing, beam steering, and correction for aberration, astigmatism, or dispersion.

Micro-fabricated electromagnets may further be combined by stacking. In one example, quadrupoles may be batch-fabricated on a wafer, then multiple of the quadrupoles stacked to form a larger-scale device.

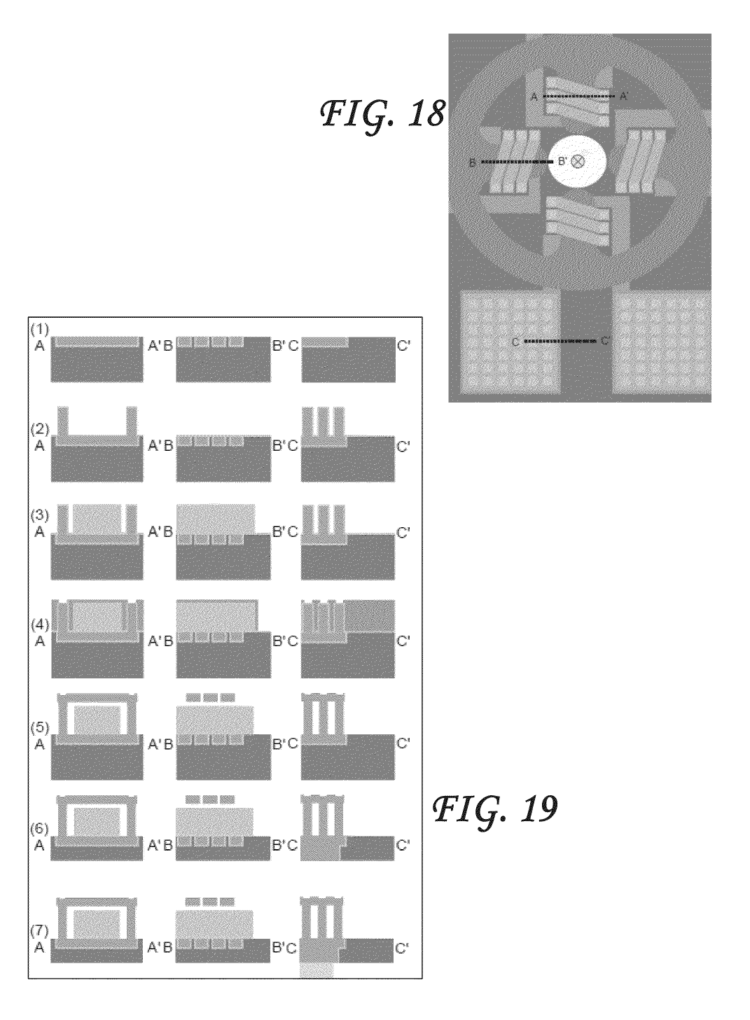

FIG. 18 illustrates an example of a fabricated quadrupole with stacking interconnects. Cross-sections A-A′ and B-B′ are across the windings of the quadrupole, and cross-section C-C′ is across a stacking interconnect. FIG. 19 illustrates an example of a seven-stage fabrication technique for fabricating a micro-machined device such as the quadrupole in FIG. 18. The A-A′, B-B′, and C-C′ cross sections of FIG. 19 refer to the cross-section indications A-A′, B-B′, and C-C′ of FIG. 18, respectively. In FIG. 19, the seven stages are labeled (1)-(7). Several of the stages are similar to those illustrated in FIGS. 5 and 12.

In a first stage of fabrication, labeled (1) in FIG. 19, a pattern for the bottom of the windings is photolithographically defined on a silicon wafer. For example, the pattern may be defined using a 5 μm thick high-aspect-ratio negative-tone photoresist, (e.g., KMPR 1005, Microchem Corp., Newton, Mass., USA), and a stepper or contact aligner (e.g., Karl Süss MA6, SÜSS MicroTec AG, Garching, Germany). Using this soft mask, trenches are etched in the silicon wafer. For example, 20 μm deep trenches may be etched in the silicon wafer using the Bosch process with a deep reactive ion etcher (e.g., SLR-770, Plasma-Therm, St Petersburg, Fla., USA). The photoresist is then removed, for example using an organic photoresist stripper (e.g., ALEG-380, J. T. Baker, Phillipsburg, N.J., USA), and the wafer surface is cleaned, such as cleaned in a mixture of 5:1 sulfuric acid and hydrogen peroxide.

The bottom windings are electrically isolated from the silicon (e.g., using an isolation layer). For example, a 500 nm thick silicon dioxide film may be grown by wet thermal oxidation (e.g., Tystar Mini 3600, Tystar Corporation, Torrance, Calif., USA). An electroforming seed is deposited on the silicon dioxide, for example by RF sputtering with 20 kV wafer bias (e.g., CVC 601, Consolidated Vacuum Corporation (was CVC, now VEECO), Plainview, N.Y., USA). Wafer bias allows coverage over a 20 μm wafer topology. The seed layer in one embodiment is 30 nm titanium to provide adhesion to the substrate and 300 nm copper to carry the electroplating current and provide a compatible surface for electroplating copper. The seed layer is cleaned, such as in 1% hydrofluoric acid, and a conductive film is added. For example, a 25 μm copper film may be electroplated from a phosphorized copper anode in a sulfate based solution (e.g., Elevate Cu 6320, Technic Inc., Rhode Island, USA). The copper film is polished back down to the silicon surface (e.g., PM5, Logitech Ltd., Glasgow, Scotland), for example by using a 100 nm aluminum oxide slurry (e.g., ALOX100, Universal Photonics, Hicksville, N.Y., USA), yielding filled trenches, which will be the bottom of the electromagnet winding pattern. The wafer is cleaned of slurry, such as with a dip in 1% hydrofluoric acid.

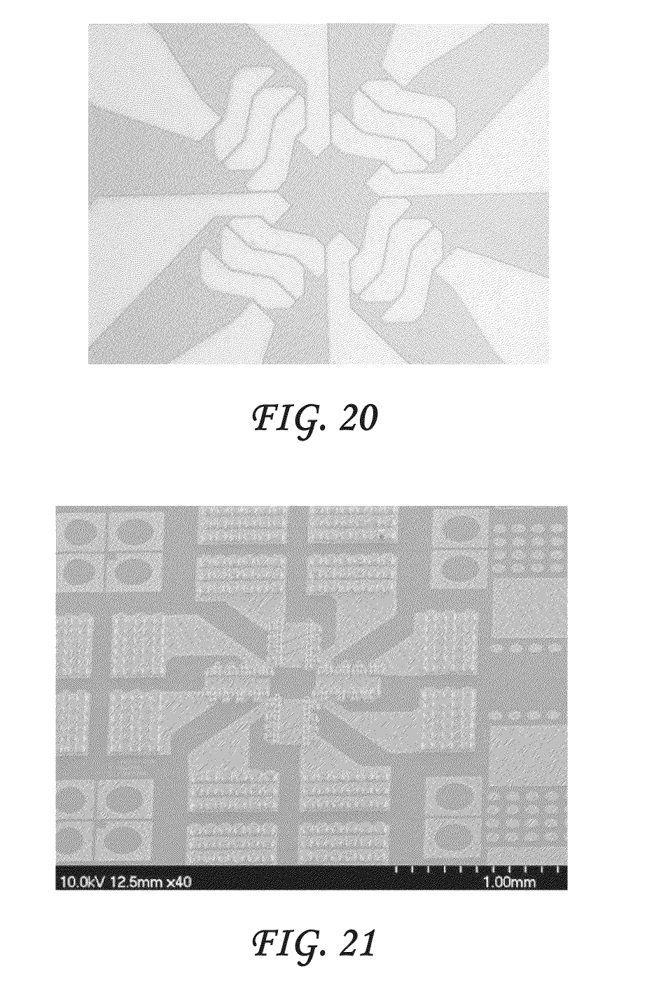

FIG. 20 is an optical microscope image of a fabricated 200 μm gap quadrupole bottom winding metal after fabrication stage (1). Copper is visible as the light colored material and silicon is visible as the darker material. The silicon dioxide layer is thinner than the resolution of the optical microscope.

In a second stage of fabrication, labeled (2) in FIG. 19, an electroforming seed is deposited on the surface of the silicon dioxide, such as by sputtering. The seed layer may be, for example, 30 nm of titanium to provide adhesion to the substrate, 300 nm of copper to carry the electroplating current and provide a compatible surface for electroplating copper, and another 30 nm of titanium to provide adhesion between the metal and the electroplating mold.

A film of photoresist is photolithographically patterned to define the geometry of the electromagnet winding interconnects. For example, a 100 μm thick film of high sidewall-aspect-ratio negative-tone photoresist (e.g., KMPR 1025, Microchem Corp., Newton, Mass., USA) may be patterned. The exposed seed layer is etched back to copper, such as in 1% hydrofluoric acid, and a copper layer is added. For example, a 100 μm thick copper may be electroplated through the mold at 5 mA/cm2. The film stack is polished down to planarize the copper surface, such as by using a 100 nm colloidal aluminum oxide slurry. The wafer is cleaned of slurry, such as with a dip in 1% hydrofluoric acid. The mold is then removed. For example, the mold is removed by plasma etching with an inductively coupled 4:1 O₂:CF₄ plasma (e.g., STS MESC Multiplex AOE, SPTS Technologies Limited, Newport, United Kingdom) using 600 W coil power and 50 W platen power. The electroplating seed is stripped, for example with a sputter etch by increasing the platen power to 200 W.

An insulating layer (or other isolation layer) is added to isolate the bottom windings and winding interconnects from the conductive magnetic core. For example, a 2 μm thick insulating layer of silicon nitride is deposited by inductively-coupled plasma enhanced chemical vapor deposition (e.g., STS MESC Multiplex CVD, SPTS Technologies Limited, Newport, United Kingdom).

FIG. 21 is a scanning electron micrograph of fabricated 200 μm gap quadrupole winding interconnects after fabrication stage (2), taken at a slight inclination to show aspect ratio. Copper is visible as lighter intensity and silicon is visible as darker intensity.

In a third stage of fabrication, labeled (3) in FIG. 19, an electroforming seed is deposited as described for stage (2). A layer of photoresist, such as a 100 μm thick film of KMPR 1025 photoresist, is photolithographically patterned into the geometry of the magnet core. Between pouring the photoresist and spinning, the film is de-gassed to remove bubbles, for example in a vacuum oven at 30 Torr and 30° C. The exposed seed layer is etched to copper, such as in 1% hydrofluoric acid, and the magnetic alloy that forms the electromagnet yoke is electroplated through the mold. The film stack is polished flat and the mold and electroplating seed are stripped as described for stage (2). An insulating layer (or other isolation layer) is added to protect the magnetic core from oxidation and improve yield (e.g., avoid shorting to the coil windings). For example, a 2 μm thick insulating layer of silicon nitride is deposited by inductively-coupled plasma enhanced chemical vapor deposition (e.g., STS MESC Multiplex CVD, SPTS Technologies Limited, Newport, United Kingdom).

In a fourth stage of fabrication, labeled (4) in FIG. 19, a layer of photoresist, such as a 100 μm layer of photoresist (e.g., SU-8 2025, Microchem Corp., Newton, Mass., USA) is used to provide a planar surface for defining the top layer of the coil windings. Between pouring the photoresist and spinning, the film is de-gassed to remove bubbles, such as in a vacuum oven at 30 Torr and 30° C. The photoresist is patterned using photolithography to define the winding interconnects and electron beam path. The film is polished flat before development using, for example, a 100 nm colloidal silica slurry. The film is then annealed, for example under vacuum for 8 hours at 200° C.

The silicon nitride covering the copper in the vias is etched to expose portions of the filled trenches, such as etching with an inductively coupled C₄F₈ plasma (e.g., STS MESC Multiplex AOE, SPTS Technologies Limited, Newport, United Kingdom).

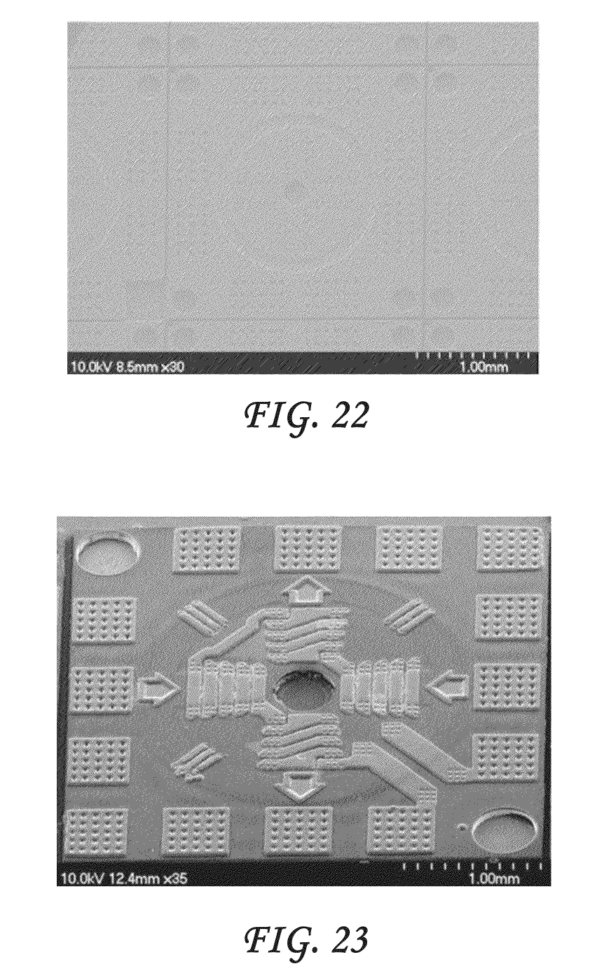

FIG. 22 is a scanning electron micrograph of a fabricated 200 μm gap quadrupole structure after fabrication stage (4). Large square openings to the stacking interconnect pads are visible, as well as small square openings to the winding interconnect landings. Die-to-die alignment holes are visible on the corners of the die, as well as the square pad zero marker indicating die orientation in the top left corner.

In a fifth stage of fabrication, labeled (5) in FIG. 19, another electroforming seed layer is added, for example sputtered on the surface (e.g., CVC 601). A photoresist (e.g., KMPR 1005) is patterned into the geometry of the top layer of the electromagnet coil windings. Copper is electroplated (e.g., Elevate Cu 6320) through the photo-patterned mold to form the winding interconnects and thereby complete the electromagnet windings. The mold and electroplating seed are stripped using a process such as described above.

FIG. 23 is a scanning electron micrograph of a fabricated 400 μm gap quadrupole electromagnet during fabrication stage (5), taken at a slight inclination.

The SU-8 is etched back using a plating mold stripping process such as described above (and as shown in FIG. 19) to prevent damage during operation.

In a sixth stage of fabrication, labeled (6) in FIG. 19, KMPR 1010 is spun on the back side of the device wafer and a through-wafer electromagnet stacking interconnect via pattern is aligned to the front side (e.g., using a Karl Süss BA6). The device side of the wafer is bonded with wax to an oxidized handle wafer for further backside processing in vacuum tools. Holes are etched from the back of the device wafer to the front, such as by using a Bosch etch (e.g., Versaline Fast Deep Silicon Etch II, OC Oerlikon, Pffiffikon, Schwyz, Switzerland), stopping on the backside of the electromagnet pads, defining the stacking interconnect vias and stopping on the handle wafer to define the multi-pole electromagnet gap. The mold is stripped and an insulating layer is added to protect the silicon from shorting to the through-wafer stacking interconnects. For example, a 2 μm thick insulating layer of silicon nitride is deposited by inductively-coupled plasma enhanced chemical vapor deposition (e.g., STS MESC Multiplex CVD). The silicon dioxide covering the backside of the copper is etched, such as with an inductively-coupled C₄F₈ plasma under high wafer bias (e.g., STS MESC Multiplex AOE) to expose the copper without etching away the silicon nitride sidewall coverage. Another electroforming seed layer is added, such as by sputtering on the surface (e.g., CVC 601), and the backside pads are patterned (e.g., KMPR 1025). Copper is electroplated, such as from an acid copper bath (e.g., Elevate Cu 6320) to a 100 μm thickness, and the backside of the wafer is ground back to the surface of the copper in the stacking interconnect, such as by using a 100 nm colloidal aluminum oxide slurry.

In a seventh stage of fabrication, labeled (7) in FIG. 19, photoresist (e.g., KMPR 1025) is patterned to define solder balls for die stacking Solder balls are electroplated and the mold is stripped from the wafer. The handle wafer and device wafer are separated by dissolving the wax, for example in 80° C. water.

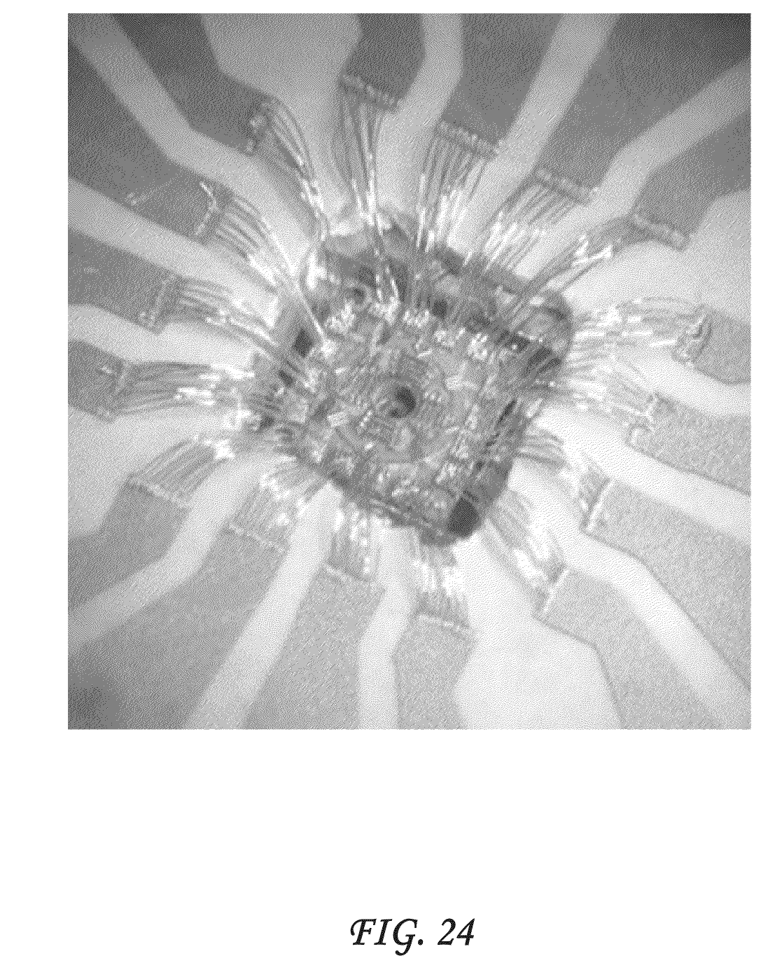

FIG. 24 is an optical microscope image, taken at a slight inclination and rotation, of a fabricated 600 μm gap quadrupole electromagnet after packaging and wirebonding to a PCB, with wire-bonding connecting the top side of the pads to a beam testing fixture.

As discussed above, once fabricated, multiple multi-pole electromagnets may be combined into a larger-scale device. In one embodiment, multiple quadrupoles are stacked and electrically connected to form a beam-manipulation device. The quadrupoles may be electrically controlled either individually or in groups to generate desired fields.

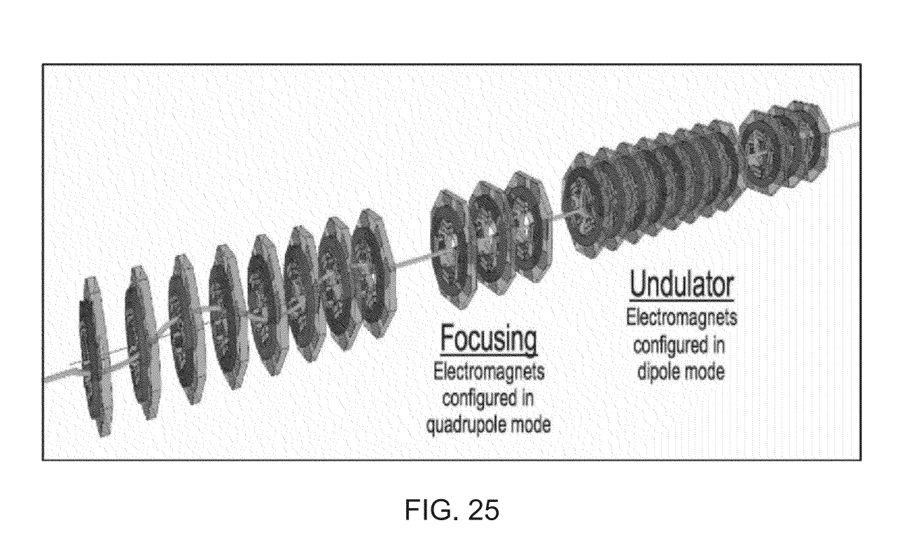

FIG. 25 illustrates stacked quadrupoles, where individual quadrupoles or groups of quadrupoles are controlled to perform beam manipulation along the length of the stacked quadrupole device. In the illustration of FIG. 25, a first group of eight quadrupoles (illustrated at the left) are controlled to function as dipoles, thereby implementing beam steering; the next three quadrupoles are controlled to function as dipoles, thereby implementing beam focusing; the next eight quadrupoles are controlled to function as dipoles with alternating fields, thereby implementing an undulator; and the final three quadrupoles are controlled to function as quadrupoles, thereby providing further focusing.

Thus, by controlling individual quadrupoles or groups of quadrupoles, beams may be manipulated in a wide variety of ways to accomplish the beam manipulation needs of the particular application. A configuration such as illustrated in FIG. 25 using alternating focusing and undulator sections would allow for maintaining beam quality in a high-gain undulator, for example. Further, a controller may be added to control the functionality of the quadrupoles in real time, providing reconfiguration at will.

When four electromagnets oriented 90° from each other are configured with a North, North, South, South, arrangement, a dipole field is produced. A dipole field will deflect a traveling charged particle perpendicular to both the field and the direction the particle is traveling. This arrangement facilitates beam steering.

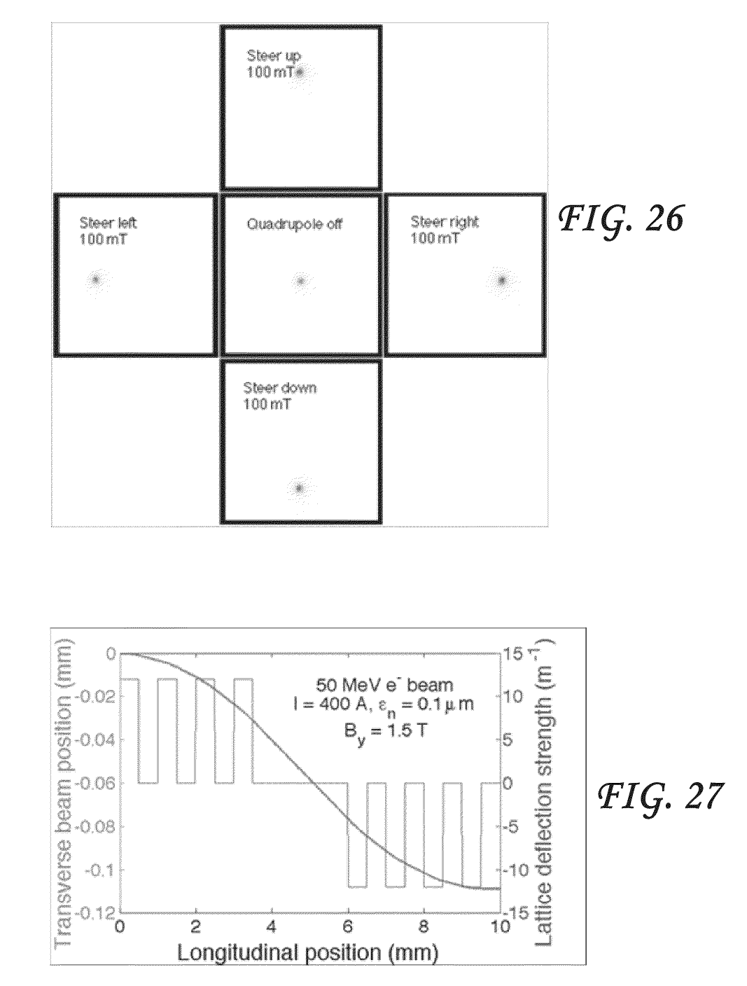

FIG. 26 illustrates beam spot steering with a single 4-pole electromagnet powered in dipole mode using a 34 kV 1 kHz 10 fC underfocused electron beam shot through a 50 μm diameter iris from an accelerated gun.

Multiple stacked multi-pole electromagnets configured as dipoles can change the transverse position of an electron beam using two consecutive multi-pole electromagnets with alternating dipole fields.

FIG. 27 is a calculated electron beam trajectory through a multi-pole electromagnet stack of eight dies programmed for a 1.5 Tesla field in the +y direction, two dies programmed for no field output, and four dies programmed for 1.5 Tesla field in the −y direction.

When alternating dipole fields are produced across many multi-pole electromagnets, an undulator field is produced, facilitating production of radiation from the traveling charged particle beam.

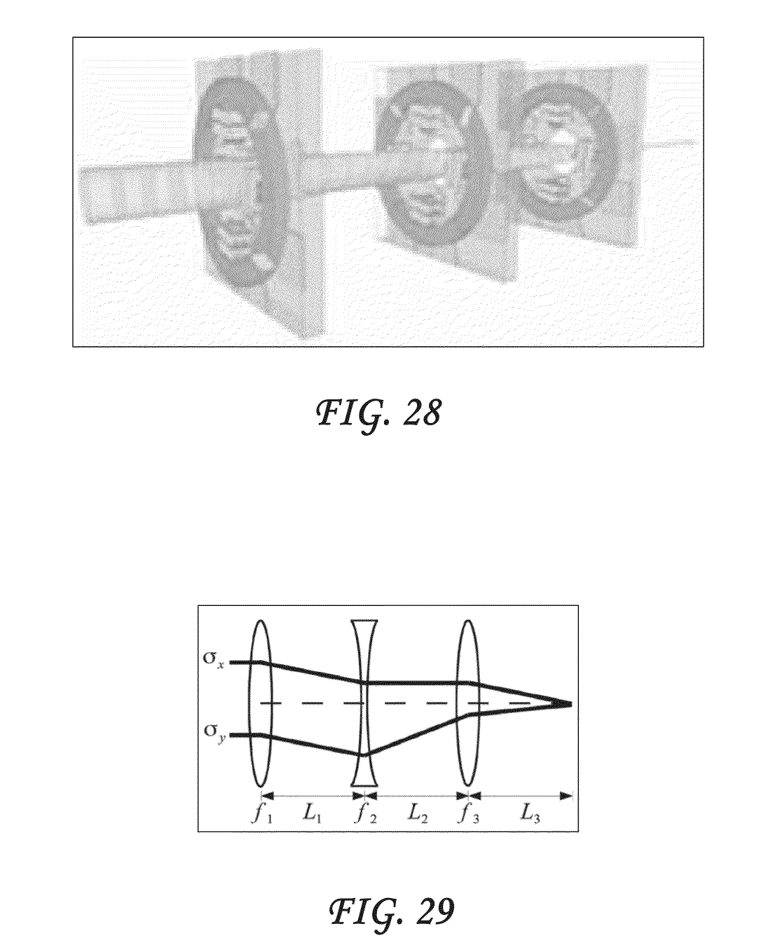

When four electromagnets oriented 90° from each other are configured in alternating North, South, North, South arrangement, a quadrupole field is produced. Quadrupole mode of operation is a configuration of magnets that focuses the electron beam in one direction perpendicular to the beam motion and defocuses in the other, via the Lorentz force, \vec{F}=q\vec{v}×\vec{B}, where \vec{F} is the force felt by a particle with charge (q) and velocity (\vec{v}) under the influence of a magnetic field (\vec{B}). By using multiple quadrupoles rotated with different orientations, a net focusing can be achieved in both transverse directions. FIG. 28 illustrates triplet geometry, where quadrupoles are rotated 90° to achieve focusing in both transverse directions. FIG. 29 illustrates focusing using triplet geometry, where σₓ and σ_{y} represent the RMS beam spot size in the two transverse directions.

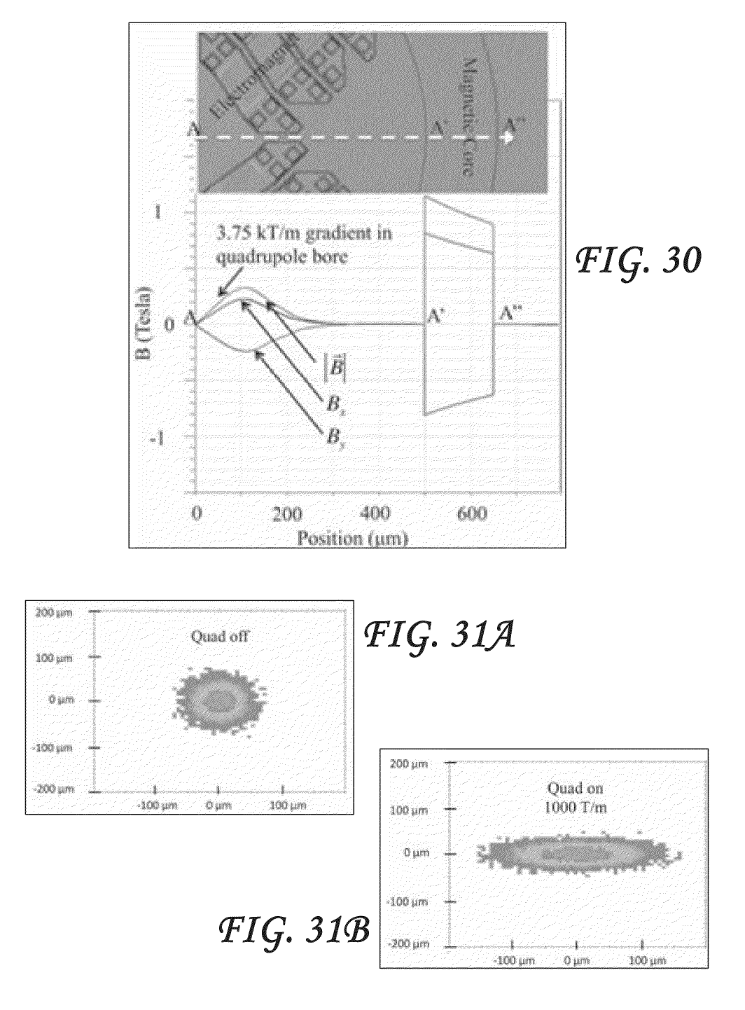

The focusing strength of the quadrupole is proportional to the magnetic field gradient, so scaling the device down while maintaining the magnetic saturation will lead to dramatic increases in magnetic field gradient (and therefore focusing strength). Because the gap between electromagnet poles in a microfabricated device can be made in a scale of hundreds of micrometers or less, field gradients in the kT/m range can be produced (as compared to the 10 T/m scale gradients produced in conventional quadrupole electromagnets). For example, a simulation of the 200 μm gap multi-pole electromagnets fabricated yields a 3.75 kT/m gradient. FIG. 30 shows a top-view subsection of a 200 μm gap multi-pole electromagnet powered in quadrupole mode at the top of the figure, and at the bottom of the figure a simulation of transverse components and magnitude of magnetic field mid-plane in the quadrupole field, assuming a 100 μm thick CoNiFe electromagnet. FIGS. 31A, 31B illustrate the effect of this gradient on a 12 MeV electron beam (PEGASUS beamline (12 MeV beam energy, 1 pC charge, 20 nm emittance, 0.05% energy spread, 200 fs bunch length)). FIG. 31A is a simulation of electron beam profile when the quadrupole is off and FIG. 31B is a simulation of electron beam profile when the quadrupole is on. As can be seen, beam shape can be substantially altered using the described microfabricated multi-pole electromagnets.

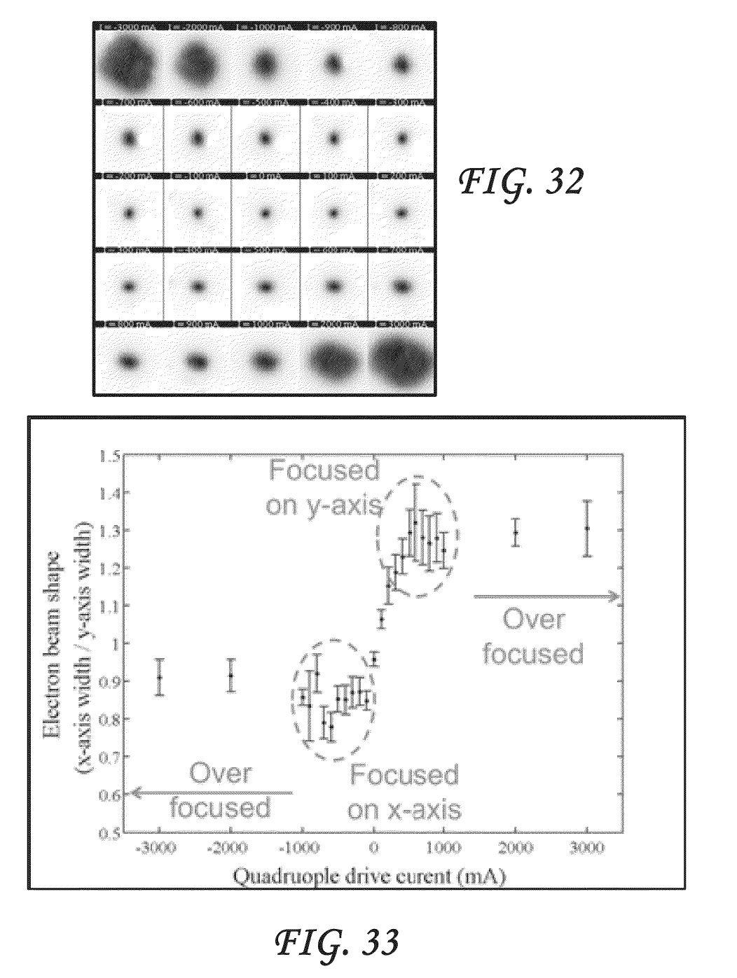

FIG. 32 illustrates focusing of an emittance-limited beam. Beam spot focusing in this example is implemented with a single multi-pole electromagnet powered in quadrupole mode using a 34 kV 1 kHz 10 fC underfocused emittance limited electron beam shot through a 50 μm diameter iris from an accelerated gun. Notice the visible change in beam shape from a circular beam at I=0 mA to an elliptical beam at I=+500 mA. Because the electron beam used for the test of FIG. 32 was low-energy and had an unstable incoming angle, the electron beam emittance limited the beam size focused by the quadrupole to no less than the size of the iris. Beam shape modulation is still visible, however, and analysis of the data clearly demonstrates focusing operation.

FIG. 33 shows an analysis of electron beam shape measurements of 1000 shots with quadrupole focusing drive current between −3 A and +3 A. Focus on the micro-channel plate imager (f=14 cm) should occur at +500 mA drive current.

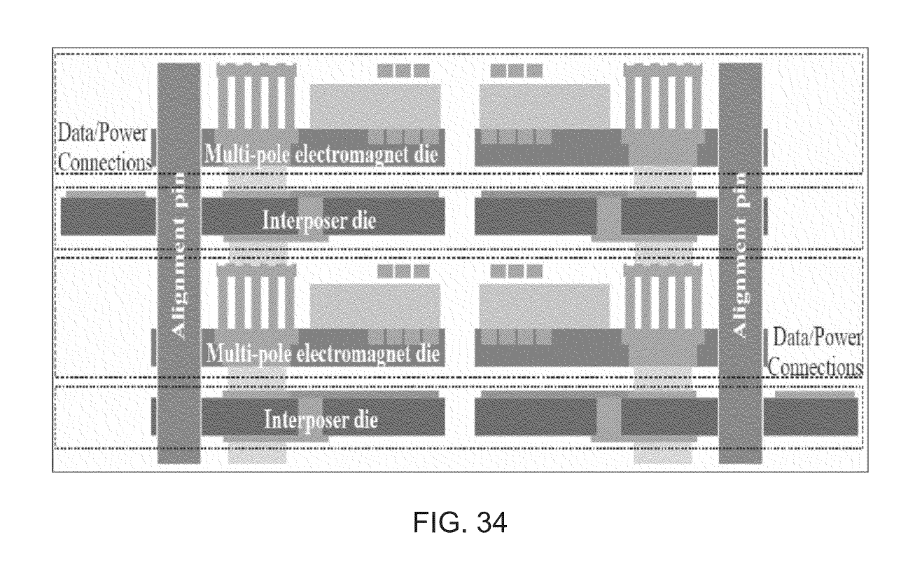

For the stacked multi-pole electromagnets, the high density of high-current wiring makes it desirable to use an interposer die between stacked electromagnet dies to facilitate the re-routing of the drive current in the electromagnet dies, as illustrated in FIG. 34. In this embodiment, multi-pole electromagnet dies are connected front-to-back with a CMOS/MEMS switch network. Pins in the corner of the dies provide coarse stacking alignment and a power and/or thermal path between dies. A low pin-count programming interface on the die edge sets the multi-pole electromagnet configuration. Thus, pre-programmed or onsite re-routing of the electromagnetic drive current may be accomplished.

Quadrupole stacks have been described by way of example. The manufacture and configuration control of other multi-pole electromagnets may be similarly performed. Additionally, although stacked multi-pole structures have been described in which each multi-pole electromagnet is of the same type, such as all quadrupoles, other stacked configurations are also within the scope of this disclosure. As one example, a stack may include a mix of quadrupoles sectupoles, and octopoles.

In addition to the applications described above for using the micro-machined multi-pole electromagnets, there are many other applications that would also benefit from the use of micro-machined multi-pole electromagnets. Some examples follow.

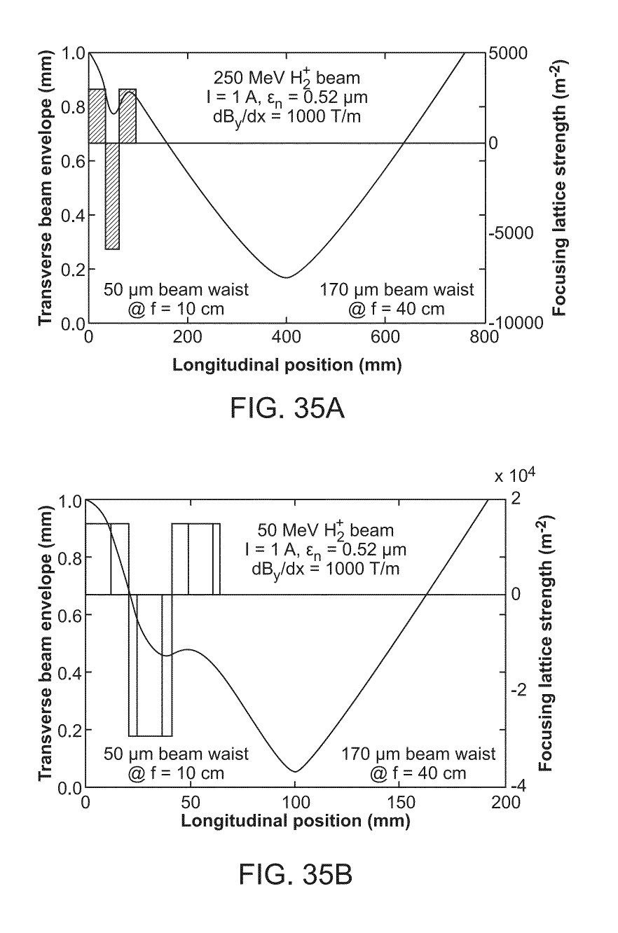

Hadron (neutron, proton, or carbon) therapy is used for treatment of a variety of prostate and brain cancers. Presently, construction of these oncology tools is limited in large part by the physical size of beam transport line and patient gantry. For instance, the gantry for the carbon therapy facility in Heidelberg, Germany is approximately 600 tons, and much smaller proton therapy gantry systems cost $40M to $70M. Because surface micro-machined multi-pole electromagnets are physically small and manufactured in a massively parallel process, steering and focusing provided by a surface micro-machined multi-pole electromagnets could reduce the size and cost of hadron therapy beam transport and focusing systems by several orders of magnitude. FIGS. 35A and 35B show focusing of the transverse beam envelope for a proton gantry focusing system, using a programmable multi-pole electromagnet lattice configuration for a proton therapy final focus stage, showing sub-0.2 mm beam width achieved for protons with a Bragg peak at 40 cm (FIG. 35A) and a sub-0.1 mm beam width achieved for protons with a Bragg peak at 10 cm (FIG. 35B).

Micro-machined multi-pole electromagnets may also be used as ion traps. Ion traps are used as residual gas analyzers in a variety of industrial plasma etching and deposition systems, as well as more general purpose scientific hardware.

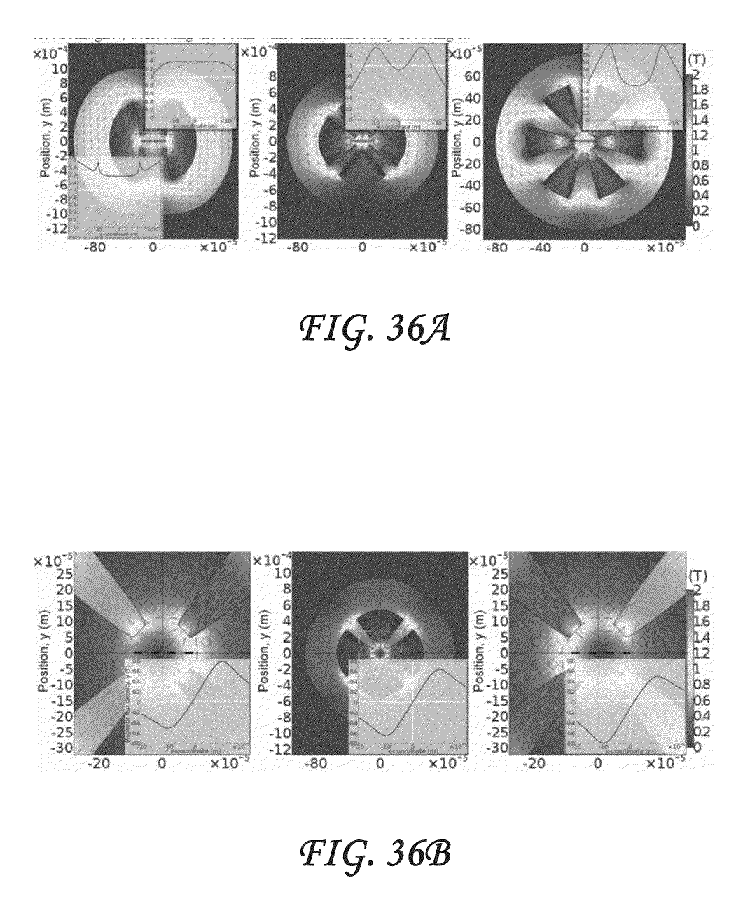

Micro-machined multi-pole electromagnets may be used for virtual field shimming, such as when the electromagnets are used in charged particle beam optics. FIG. 36A illustrates dipole fields from 2, 4, and 6-pole Co₅₈Ni₁₃Fe₃₉ core electromagnets at saturation, where varying darkness represents field intensity, arrows show field direction, and inset plots show field distribution across the n-pole electromagnet center. Fields produced by surface-micro-machined 2-pole electromagnets can be made very uniform throughout the majority of the gap by appropriately shaping the pole tip. Alignment of higher order electromagnet dipole fields with the charged particle beam, however, can be challenging because of the smaller good field region. To address this, the good field region can be spatially translated by adjusting the drive current of individual electromagnet sets The simplicity of changing electromagnet drive current enables computer-based automation of field tuning and beam alignment using a diagnostic screen and camera (i.e., “virtual shimming” as opposed to physically moving the magnet). Similarly, magnetic field imperfections due to manufacturing defects or misalignment can be mitigated by changing individual electromagnet drive current. FIG. 36B illustrates quadrupole field from O-pole CoNiFe core electromagnets at saturation with a superimposed dipole field shifting the quadrupole field centroid left, with the quadrupole field centered, and shifting the quadrupole field centroid right. The level of darkness indicates field intensity and the arrows show field direction. The center plot shows quadrupole mode without superimposed dipole fields. The outside plots show the field centroid shifted with a horizontal dipole. Inset plots show field distribution across the quadrupole center.

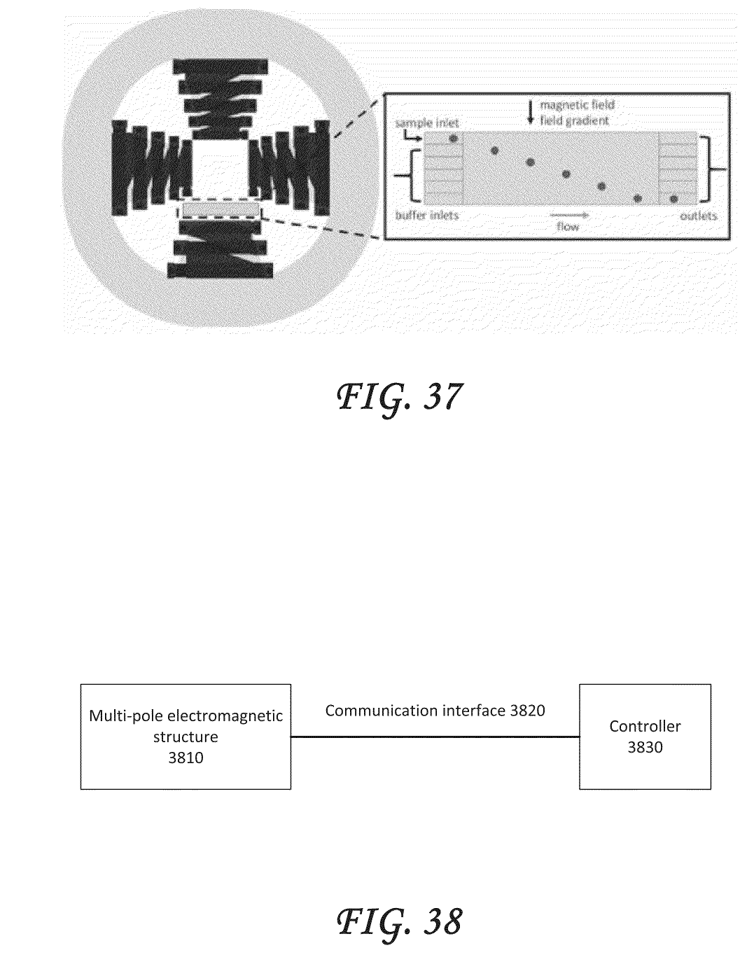

Micro-machined multi-pole electromagnets may be used with integrated microfluidics for magnetophoresis (e.g., particle sorting by magnetization or electron spin). Typically, permanent magnets are used for magnetization of particles and field gradients. For example, NdFeB magnets are capable of producing up to approximately 1 Tesla fields with approximately 200 T/m gradients. In contrast, N-pole electromagnets can produce comparable fields with approximately 1 kT/m gradients, such as for particle steering. FIG. 37 illustrates the use of a non-symmetric 4-pole electromagnet produce a region of both high field density and high field gradient. Electrical control of the field profile can allow switching between uninhibited flow, steering, and trapping of particles. Due to large surface topologies, standard PDMS methods of channel fabrication are difficult. A channel fabrication method involving positive tone resist sacrificial material and negative tone resist channel structure is applied: a positive tone resist is applied to a bottom surface of a channel and patterned; a negative tone resist is applied over the patterned positive tone resist, and spun (between pouring the photoresist and spinning, de-gassing may be performed, for example, in a vacuum oven at 30 Torr for 30 seconds); the negative tone resist is patterned, and the positive tone resist is stripped.

Programmable manipulation of magnetic particles for lab-on-a-chip applications of the micro-machined multi-pole electromagnets includes: electrically compensate for fluid flow and particle susceptibilities; configuration of an undulator for periodic exposure of particles to different reagents; and switching connections between upstream sources and downstream experiments. As can be seen, the micro-machined multi-pole electromagnets along with programmable manipulation of the same, provide for improved cost efficiency, robustness, and performance of analytical biochemistry experiments.

Micro-machined multi-pole electromagnets may be used as the basis for single-shot electron microscopy, providing many opportunities for compact instruments to be developed with good time and spatial resolution (e.g., time resolution of 1000 femtoseconds and spatial resolution of 10 Angstroms). Such instruments would be beneficial, for example, in the imaging of chemical bonds being made and broken, phase transformations, magnetic domain movement, melting and solidification, structural changes in biology, visualizing nucleation and damage growth, and studying dislocation dynamics, among other areas. Such instruments would overcome problems associated with existing techniques, as well as fill the gap where other instruments are not available. For example, state-of-the-art ultrafast electron microscopy cannot image with a single shot, but instead relies on pump-probe techniques that are limited to precisely repeatable phenomena. For another example, the Rose criterion requires approximately 10⁸ e⁻ per megapixel to resolve an image; however, increased beam energy of a transmission electron microscope (TEM) is needed to preserve the temporal resolution of the electron beam, which in turn requires an increase in the focusing strength needed in the system. One available such TEM using traditional magnetic lenses is the Hitachi HU-3000, which is about three stories tall and weighs approximately 140 metric tons. By comparison, the micro-machined multi-pole electromagnets of this disclosure enable an equivalent instrument in a compact size of about two meters tall.

The development of compact, programmable, high-energy light sources will enable proliferation of unique imaging technologies, providing coherent narrowband X-Rays for phase contrast X-Ray imaging (soft tissue radiology) and rapid X-Ray polarization control for photoemission electron microscopy (multiferroics and spintronics). The device will extend the capabilities of facilities such as the Advanced Photon Source and will be an integral component of a new class of bench-top FELs, undulator sources, and inverse FEL accelerators.

Thus, among other uses, the micro-machined multi-pole electromagnets of this disclosure may be used in a particle beam steering optics device, a particle beam focusing optics device, a mass spectrometer, a single cell MRI imaging device, a magnetophoresis device, a diamagnetophoresis device, an ion trap, a high energy beam focusing device, a low energy beam focusing device, and an electron imaging device that directly or indirectly records the presence of electrons in space and time.

An embodiment of the disclosure relates to a non-transitory computer-readable storage medium having computer code thereon for performing various computer-implemented operations. The term “computer-readable storage medium” is used herein to include any medium that is capable of storing or encoding a sequence of instructions or computer codes for performing the operations, methodologies, and techniques described herein. The media and computer code may be those specially designed and constructed for the purposes of the disclosure, or they may be of the kind well known and available to those having skill in the computer software arts. Examples of computer-readable storage media include, but are not limited to: magnetic media such as hard disks, floppy disks, and magnetic tape; optical media such as CD-ROMs and holographic devices; magneto-optical media such as optical disks; and hardware devices that are specially configured to store and execute program code, such as application-specific integrated circuits (“ASICs”), programmable logic devices (“PLDs”), ROM and RAM devices, firmware programmed into a field programmable gate array (FPGA), and circuits integrated into a MEMS device or packaged with a MEMS device. Examples of computer code include machine code, such as produced by a compiler, and files containing higher-level code that are executed by a computer using an interpreter or a compiler. For example, an embodiment of the disclosure may be implemented using Java, C++, or other object-oriented programming language and development tools. Additional examples of computer code include encrypted code and compressed code. Moreover, an embodiment of the disclosure may be downloaded as a computer program product, which may be transferred from a remote computer (e.g., a server computer) to a requesting computer (e.g., a client computer or a different server computer) via a transmission channel. Another embodiment of the disclosure may be implemented in hardwired circuitry in place of, or in combination with, machine-executable software instructions.

FIG. 38 is illustrative, showing in block diagram form a multi-pole electromagnet structure 3810 connected via a communication interface 3820 with a controller 3830. The multi-pole electromagnet structure 3810 includes one or more multi-pole electromagnets. Communications interface 3820 may be any serial or parallel interface for communication, including wireless interfaces, including single wire or multi-wire connections for analog or digital information, and including conductive traces in a semiconductor device. Controller 3830 includes a storage medium having computer code thereon for controlling electromagnet structure 3810. Controller 3830 may control electromagnet structure 3810 by controlling positioning of one or more multi-pole electromagnets in electromagnet structure 3810, and/or by controlling the flow of current through one or more of the windings of electromagnets in electromagnet structure 3810. In one example, controller 3830 is a computing device, such as a computer, server, smart phone, tablet, or other computing device, and controller 3830 communicates with electromagnet structure 3810 by way of a communication interface 3820 for off-line or real-time configuration and/or monitoring. In another embodiment, controller 3830 is co-located or co-packaged with electromagnet structure 3810, and communicates with electromagnet structure 3810 by way of a communication interface 3820 for off-line or real-time configuration and/or monitoring. In yet another embodiment, as seen in the conceptual drawing of one stacked embodiment in FIG. 34, controller 3830 may be integrated within an electromagnetic structure 3810, where integration may be controller 3830 and electromagnets on separate dies within the electromagnetic structure 3810, or controller 3830 co-fabricated with one or more multi-pole electromagnets on a die within the electromagnetic structure 3810.

As used herein, the terms “substantially” and “about” are used to describe and account for small variations. When used in conjunction with an event or circumstance, the terms can refer to instances in which the event or circumstance occurs precisely as well as instances in which the event or circumstance occurs to a close approximation. For example, the terms can refer to less than or equal to +10%, such as less than or equal to +5%, less than or equal to +4%, less than or equal to +3%, less than or equal to +2%, less than or equal to +1%, less than or equal to +0.5%, less than or equal to +0.1%, or less than or equal to +0.05%.

While the disclosure has been described with reference to the specific embodiments thereof, it should be understood by those skilled in the art that various changes may be made and equivalents may be substituted without departing from the true spirit and scope of the disclosure as defined by the appended claims. In addition, many modifications may be made to adapt a particular situation, material, composition of matter, method, operation or operations, to the objective, spirit and scope of the disclosure. All such modifications are intended to be within the scope of the claims appended hereto. In particular, while certain methods may have been described with reference to particular operations performed in a particular order, it will be understood that these operations may be combined, sub-divided, or re-ordered to form an equivalent method without departing from the teachings of the disclosure. Accordingly, unless specifically indicated herein, the order and grouping of the operations is not a limitation of the disclosure.

What is claimed is:

1. A structure, comprising: a plurality of electromagnets with sub-100 micrometer feature size, each electromagnet including:
a substrate defining a plurality of trenches;
a plurality of conductive fillers disposed in respective ones of the plurality of trenches;
a first isolation layer disposed over the plurality of conductive fillers such that a portion of each conductive filler is exposed by the first isolation layer;
a core disposed over the first isolation layer;
a second isolation layer covering the core, the second isolation layer having a top surface;
a plurality of winding interconnects extending from a plane defined by the top surface of the second isolation layer to the plurality of conductive fillers, wherein each winding interconnect contacts one of the plurality of conductive fillers on a portion exposed by the first isolation layer; and
a conductive layer including a plurality of upper connectors, each upper connector disposed to electrically connect at least two winding interconnects positioned on opposite sides of the core;
wherein the plurality of conductive fillers, the plurality of winding interconnects, and the plurality of upper connectors are electrically connected to form windings around the core.

2. The structure of claim 1, wherein the core of at least one of the plurality of electromagnets is a yoke.

3. The structure of claim 1, wherein a field gradient of at least one of the plurality of electromagnets exceeds at least one of 570 Tesla/meter, 700 Tesla/meter, 1,000 Tesla/meter, 1,500 Tesla/meter, 2,000 Tesla/meter, and 3,000 Tesla/meter, 4,000 Tesla/meter, 5,000 Tesla/meter, 6,000 Tesla/meter, 7,000 Tesla/meter, 8,000 Tesla/meter, 9,000 Tesla/meter, and 10,000 Tesla/meter, and 20,000 Tesla/meter.

4. The structure of claim 1, wherein the plurality of electromagnets is formed as an n-tupole, wherein ‘n’ is an integer.

5. The structure of claim 1, wherein the plurality of electromagnets is formed as a plurality of multi-pole electromagnets positioned adjacent to each other.

6. The structure of claim 5, further comprising a plurality of stacking interconnects, each stacking interconnect extending between the substrates of two adjacent multi-pole electromagnets.

7. The structure of claim 6, configured for implementation in one of a particle beam steering optics device, a particle beam focusing optics device, a mass spectrometer, a single cell MRI imaging device, a magnetophoresis device, a diamagnetophoresis device, an ion trap, a high energy beam focusing device, a low energy beam focusing device, and an electron imaging device that directly or indirectly records the presence of electrons in space and time.

8. The structure of claim 1, wherein, for at least one of the plurality of electromagnets, the windings are a plurality of windings individually controlled, thereby configuring the electromagnet for a desired field.

9. A multi-pole electromagnet structure with sub-100 micrometer feature size, comprising:
a substrate defining a plurality of trenches;
a plurality of conductive fillers disposed in respective ones of the plurality of trenches;
a first isolation layer disposed over the plurality of conductive fillers such that a portion of each conductive filler is exposed by the first isolation layer;
a core disposed over the first isolation layer;
a second isolation layer covering the core, the second isolation layer having a top surface;
a plurality of winding interconnects extending from a plane defined by the top surface of the second isolation layer to the plurality of conductive fillers, wherein each winding interconnect contacts one of the plurality of conductive fillers on a portion exposed by the first isolation layer; and
a conductive layer including a plurality of upper connectors, each upper connector disposed to electrically connect at least two winding interconnects positioned on opposite sides of the core;
wherein the plurality of conductive fillers, the plurality of winding interconnects, and the plurality of upper connectors are electrically connected to form windings around the core.

10. The multi-pole electromagnet structure of claim 9, wherein the core is a yoke.

11. The multi-pole electromagnet structure of claim 9, wherein a field gradient of at least one of the plurality of electromagnets exceeds at least one of 570 Tesla/meter, 700 Tesla/meter, 1,000 Tesla/meter, 1,500 Tesla/meter, 2,000 Tesla/meter, 3,000 Tesla/meter, 4,000 Tesla/meter, 5,000 Tesla/meter, 6,000 Tesla/meter, 7,000 Tesla/meter, 8,000 Tesla/meter, 9,000 Tesla/meter, 10,000 Tesla/meter, and 20,000 Tesla/meter.

12. The multi-pole electromagnet structure of claim 9, formed as an undulator.

13. The multi-pole electromagnet structure of claim 9, formed as an n-tupole, where n is an integer greater than or equal to two.

14. An electromagnet structure, comprising:
a plurality of multi-pole electromagnets each having a plurality of windings, wherein the windings of the plurality of multi-pole electromagnets are controlled individually or in groups to selectively configure each of the plurality of multi-pole electromagnets.

15. The electromagnet structure of claim 14, having sub-100-micrometer feature size.

16. The electromagnet structure of claim 14, further comprising a controller, wherein each winding of the plurality of multi-pole electromagnets is individually controlled by the controller.

17. The electromagnet structure of claim 14, including groups of multi-pole electromagnets configured as quadrupoles alternating with groups of multi-pole electromagnets configured as dipoles.

18. The electromagnet structure of claim 14, wherein the plurality of multi-pole electromagnets are stacked, and electrically connected together.

19. The electromagnet structure of claim 14, configured for net focusing or defocusing of a particle beam, or singular focusing or defocusing of a particle beam, in each of two transverse axes.

20. The electromagnet structure of claim 14, configured to correct at least one of spherical aberration and astigmatism in a particle beam.
